(19) United States
(12) Patent Application Publication
(10) Pub. No.: US 2023/0211454 A1
(43) Pub. Date: Jul. 6, 2023

(54) LAMINATED POLISHING PAD

(71) Applicant: TOKUYAMA CORPORATION, Shunan-shi, Yamaguchi (JP)

(72) Inventors: Yasutomo SHIMIZU, Tsukuba-shi (JP); Takayoshi KAWASAKI, Tsukuba-shi (JP); Junji MOMODA, Shimonoseki-shi (JP); Mitsuki TOCHI, Urayasu-shi (JP)

(73) Assignee: TOKUYAMA CORPORATION, Shunan-shi, Yamaguchi (JP)

(21) Appl. No.: 17/927,669

(22) PCT Filed: May 27, 2021
(86) PCT No.: PCT/JP2021/020276

§ 371 Date: Nov. 23, 2022

(30) Foreign Application Priority Data
May 28, 2020 (JP) 2020-093007

(51) Int. Cl. B24B 37/22; B24B 37/24

(52) U.S. Cl. CPC B24B 37/22; B24B 37/24

(57) ABSTRACT

The CMP laminated polishing pad of the present invention includes at least a polishing layer and an under layer, wherein the under layer contains a resin obtained by polymerizing a polymerizable composition containing: (A) a polyrotaxane monomer having at least two polymerizable functional groups in a molecule; and (B) a polymerizable monomer other than the polyrotaxane monomer having at least two polymerizable functional groups in a molecule. According to the present invention, a polishing pad having not only good wear resistance but also excellent polishing characteristics (high polishing rate, low scratch property, and high flatness) can be provided.

### TECHNICAL FIELD

The present invention relates to a laminated polishing pad.

### BACKGROUND ART

A polishing member is a material used when flattening a counterpart member (member to be polished) with a polishing agent. Specifically, the polishing member is used to flatten a surface of a member to be polished by supplying a polishing agent such as slurry to the surface and bringing the polishing member into sliding contact with the surface. For example, a polishing pad is included.

In general, as a polishing member, a material having excellent wear resistance and high durability over a long period of time is always desired from the viewpoints of cost reduction, stable production, and improvement in productivity. For this reason, many polyurethane (urea) resins are used for such polishing members.

Specifically, the polishing member is used as a polishing pad material (hereinafter also referred to as a polishing pad) in a Chemical Mechanical Polishing (CMP) method. The CMP method is a polishing method that imparts excellent surface flatness, and is particularly employed in the manufacturing process of liquid crystal displays (LCDs), glass substrates for hard disks, silicon wafers, and semiconductor devices.

In the CMP method, a method of polishing by supplying a slurry (polishing agent) in which abrasive grains are dispersed in an alkaline solution or an acid solution during polishing processing is generally employed. That is, a member to be polished is flattened by a mechanical action of the abrasive grains in a slurry and a chemical action of the alkaline solution or the acid solution. Usually, the slurry is supplied to a surface of a member to be polished, and a polishing pad material is brought into contact with the surface while sliding a polishing pad material, thereby flattening the surface of the member to be polished.

As a material for such a polishing pad, as described above, a polishing material composed of a polyurethane (urea) resin obtained from a urethane-based curable composition is known (see PTL 1).

As a required characteristic of the polishing pad, an ability to uniformly polish the entire wafer is required in addition to a local flattening ability. However, a conventional polishing pad made of a polyurethane (urea) resin has a relatively high hardness and is not easily deformed, and is generally excellent in polishing rate, local flattening ability, and repetitive polishing accuracy, but it is difficult to apply a uniform pressure to the entire surface of a wafer due to insufficient cushioning properties, and the polishing accuracy tends to decrease.

Therefore, in order to prevent such a decrease in polishing accuracy, usually a soft under layer is separately provided on the back surface of the polishing pad made of polyurethane (urea) resin, and polishing processing is performed. PTL 2 discloses that the compression ratio and thicknesses of the polishing layer and the under layer are controlled to ensure the followingness to the wafer surface and to obtain both uniformity and flatness.

### CITATION LIST

### Patent Literature

PTL1: JP 2007-77207 A

PTL2: JP 2020-037182 A

PTL3: WO 2018/092826 A

### SUMMARY OF INVENTION

### Technical Problem

However, in recent years, with miniaturization of wiring, further improvement in polishing characteristics of the laminated polishing pad as described above has been required, and there has been room for improvement in conventional techniques.

Accordingly, an object of the present invention is to provide a laminated polishing pad having an under layer and capable of exhibiting excellent polishing characteristics.

### Solution to Problem

The present inventors have conducted intensive studies in order to solve the above problems.

In recent years, there has been disclosed a polishing pad utilizing the ability of a polyrotaxane containing an axis molecule and a cyclic molecule clathrating the axis molecule, the cyclic molecule being able to slide on the axis molecule (see PTL 3). According to this method, a polishing pad having not only good wear resistance but also excellent polishing characteristics (high polishing rate, low scratch property, and high flatness) can be obtained.

The present inventors have considered that a more excellent CMP laminated polishing pad can be obtained by using a cured body into which a polyrotaxane is introduced in an under layer, and have conducted various studies. As a result, the present inventors have found that the above-mentioned problems can be solved by a CMP laminated polishing pad including at least a polishing layer and an under layer, wherein the under layer contains a resin obtained by polymerizing a polymerizable composition having a specific composition.

That is, the present invention relates to the following [1] to [9].

[1] A CMP laminated polishing pad including at least a polishing layer and an under layer, wherein the under layer contains a resin obtained by polymerizing a polymerizable composition containing: (A) a polyrotaxane monomer having at least two polymerizable functional groups in a molecule; and (B) a polymerizable monomer other than the polyrotaxane monomer (A) having at least two polymerizable functional groups in a molecule.

[2] The CMP laminated polishing pad as set forth in [1], wherein the content of the polyrotaxane monomer (A) having at least two polymerizable functional groups in a molecule in the polymerizable composition is 3 to 50 parts by mass with respect to 100 parts by mass of the sum of the content of the polyrotaxane monomer (A) having at least two polymerizable functional groups in a molecule and the content of the polymerizable monomer (B) other than the polyrotaxane monomer (A) having at least two polymerizable functional groups in a molecule.

[3] The CMP laminated polishing pad as set forth in [1] or [2], wherein the polyrotaxane monomer (A) having at least two polymerizable functional groups in a molecule is a polyrotaxane monomer in which a side chain having a polymerizable functional group is introduced into at least a part of a cyclic molecule in a composite molecular structure composed of an axis molecule and the cyclic molecule clathrating the axis molecule.

[4] The CMP laminated polishing pad as set forth in any one of [1] to [3], wherein the polymerizable monomer (B) other than the polyrotaxane monomer (A) having at least two polymerizable functional groups in a molecule is an iso(thio)cyanate compound having at least two iso(thio)cyanate groups as polymerizable functional groups.

[5] The CMP laminated polishing pad as set forth in any one of [1] to [4], wherein the under layer has a compression ratio of 1.0% or more and 40.0% or less.

[6] The CMP laminated polishing pad as set forth in any one of [1] to [5], wherein the under layer has a Shore hardness of less than 50D.

[7] The CMP laminated polishing pad as set forth in any one of [1] to [6], wherein a compression ratio of the under layer is larger than a compression ratio of the polishing layer, and a Shore hardness of the under layer is smaller than a Shore hardness of the polishing layer.

[8] The CMP laminated polishing pad as set forth in any one of [1] to [7], wherein the under layer contains a foamed polyurethane (urea) resin obtained by polymerizing the polymerizable composition.

[9] The CMP laminated polishing pad as set forth in any one of [1] to [7], wherein the under layer is composed of a nonwoven fabric containing a polyurethane (urea) resin obtained by polymerizing the polymerizable composition.

### Advantageous Effects of Invention

The CMP laminated polishing pad of the present invention has an excellent polishing rate, flatness and uniformity with respect to the object to be polished.

Although its action is not clear, it is presumed as follows.

It is generally known that polyrotaxane imparts stress dispersion performance capable of relaxing a stress concentration site and excellent elastic recovery performance against deformation by movement of a cyclic molecule in polyrotaxane on an axis molecule.

In the present invention, it is considered that the polyrotaxane is not simply blended in the resin constituting the under layer of the CMP laminated polishing pad, but the polyrotaxane is used as a monomer as one constituent of the resin constituting the under layer, whereby the above-mentioned stress dispersion performance and elastic recovery performance are imparted to the whole resin, and an excellent CMP laminated polishing pad can be provided.

### DESCRIPTION OF EMBODIMENTS

The CMP laminated polishing pad of the present invention is a CMP laminated polishing pad including at least a polishing layer and an under layer, wherein the under layer contains a resin obtained by polymerizing a polymerizable composition containing (A) a polyrotaxane monomer having at least two polymerizable functional groups in a molecule (hereinafter referred to as a “polyrotaxane monomer (A)” or a “component (A)”) and (B) a polymerizable monomer other than the polyrotaxane monomer (A) having at least two polymerizable functional groups in a molecule (hereinafter referred to as a “polymerizable monomer (B)” or a “component (B)”).

Hereinafter, each component will be described.

### <(A) Polyrotaxane Monomer>

Polyrotaxane is a known compound, and has a complex molecular structure formed of a chain-like axis molecule and a cyclic molecule. That is, it has a structure in which a chain-like axis molecule is clathrated with a cyclic molecule, and the axis molecule penetrates the inside of the ring of the cyclic molecule. Therefore, since the cyclic molecule can slide freely on the axis molecule, bulky terminal groups are usually formed at both terminals of the axis molecule to prevent the cyclic molecule from falling off the axis molecule.

In general, in the above structure, the case where a plurality of cyclic molecules are present is referred to as “polyrotaxane”, but in the present invention, the case where one cyclic molecule is present is also referred to as “polyrotaxane”.

In the polyrotaxane, the cyclic molecule can slide on the axis molecule as described above. Therefore, it is considered that performance called sliding elasticity is exhibited and excellent characteristics can be exhibited. In the present invention, by using polyrotaxane as one constituent of the resin constituting the under layer of the CMP laminated polishing pad, excellent polishing characteristics can be exhibited.

The polyrotaxane monomer (A) used in the present invention is not particularly limited as long as it is a polyrotaxane having a polymerizable functional group that can be polymerized with a component (B) to be described later, and can be synthesized by a known method, for example, a method described in WO2015/068798. The constitution of the component (A) will be described in detail.

The axis molecule of the polyrotaxane monomer (A) used in the present invention is not particularly limited as long as it can penetrate the ring of the cyclic molecule, and a linear or branched polymer is generally used.

Examples of the polymer used for such an axis molecule include polyvinyl alcohol, polyvinyl pyrrolidone, cellulose resin (carboxymethyl cellulose, hydroxyethyl cellulose, hydroxypropyl cellulose, and the like), polyacrylamide, polyethylene oxide, polyethylene glycol, polypropylene glycol, polyvinyl acetal, polyvinyl methyl ether, polyamine, polyethylenimine, casein, gelatin, starch, olefin resin (polyethylene, polypropylene, and the like), polyester, polyvinyl chloride, styrene resin (polystyrene, acrylonitrile-styrene copolymer resin, and the like), acrylic resin (poly(meth)acrylate acid, polymethylmethacrylate, polymethylacrylate, acrylonitrile-methyl acrylate copolymer resin, and the like), polycarbonate, polyurethane, vinyl chloride-vinyl acetate copolymer resin, polyvinyl butyral, polyisobutylene, polytetrahydrofuran, polyaniline, acrylonitrile-butadiene-styrene copolymer (ABS resin), polyamide (nylon or the like), polyimide, polydiene (polyisoprene, polybutadiene, and the like), polysiloxane (polydimethylsiloxane or the like), polysulfone, polyimine, poly acetic anhydride, polyurea, polysulfide, polyphosphazene, polyketone polyphenylene, polyhalo olefin, and the like. These polymers may be appropriately copolymerized, or may be modified.

In the present invention, the polymer used for the axis molecule is preferably polyethylene glycol, polyisoprene, polyisobutylene, polybutadiene, polypropylene glycol, polytetrahydrofuran, polydimethylsiloxane, polyethylene, polypropylene, polyvinyl alcohol or polyvinyl methyl ether, and most preferably polyethylene glycol.

The molecular weight of the polymer used for the above-described axis molecule is not particularly limited, but if it is too large, when it is mixed with other polymerizable monomers and the like, the viscosity increases, handling becomes difficult, and the compatibility tends to deteriorate. From such a viewpoint, the weight average molecular weight Mw of the axis molecule is preferably in a range of 400 to 100,000, more preferably in a range of 1,000 to 50,000, and particularly more preferably in a range of 2,000 to 30,000. The weight average molecular weight Mw is a value measured by a gel permeation chromatography (GPC) measurement method described in Examples to be described later.

The polymer used for the above-described axis molecule preferably has bulky groups at both terminals so that the ring penetrating the ring of the cyclic molecule does not come off. The bulky group formed at both terminals of the polymer used for the axis molecule is not particularly limited as long as it is a group that prevents the elimination of the cyclic molecule from the axis molecule, and examples thereof include an adamantyl group, a trityl group, a fluoresceinyl group, a dinitrophenyl group, and a pyrenyl group from the viewpoint of bulkiness, and an adamantyl group is particularly preferable from the viewpoint of ease of introduction.

On the other hand, the cyclic molecule of the polyrotaxane monomer (A) used in the present invention may be one having a ring of a size capable of clathrating the above-mentioned axis molecule, and examples of such a ring include a cyclodextrin ring, a crown ether ring, a benzo crown ring, a dibenzo crown ring, and a dicyclohexano crown ring, and a cyclodextrin ring having a reactive functional group in the cyclic molecule is particularly preferable as described later.

The cyclodextrin ring includes an a-form (ring internal diameter: 0.45 to 0.6 nm), a β-form (ring internal diameter: 0.6 to 0.8 nm), and a γ-form (ring internal diameter: 0.8 to 0.95 nm). Mixtures of these may also be used. In the present invention, α-cyclodextrin ring and β-cyclodextrin ring are particularly preferred, and α-cyclodextrin ring is most preferred.

In the above-described cyclic molecules, one or more cyclic molecules are clathrated with one axis molecule. When the maximum clathrate number of the cyclic molecules that can be clathrated with one axis molecule is 1.0, the clathrate number of the cyclic molecules is preferably 0.8 or less at the maximum. When the clathrate number of the cyclic molecules is too large, the cyclic molecules are densely present with respect to one axis molecule. As a result, the mobility (slide width) tends to decrease. In addition, the molecular weight of the polyrotaxane monomer (A) itself increases. Therefore, when it is used in a polymerizable composition, the handleability of the polymerizable composition tends to decrease. Therefore, it is more preferable that one axis molecule is clathrated with at least two or more cyclic molecules, and the clathrate number of the cyclic molecules is in a range of 0.5 or less at the maximum.

The maximum clathrate number of the cyclic molecules with respect to one axis molecule can be calculated from the length of the axis molecule and the thickness of the ring of the cyclic molecule. For example, when the chain-like portion of the axis molecule is formed of polyethylene glycol and the cyclic molecule is an α-cyclodextrin ring, the maximum clathrate number is calculated as follows. That is, two polyethylene glycol repeating units [—CH₂—CH₂O—] are approximate to the thickness of one α-cyclodextrin ring. Therefore, the number of repeating unit is calculated from the molecular weight of the polyethylene glycol, and ½ of the number of repeating unit is determined as the maximum clathrate number of the cyclic molecules. Assuming that the maximum clathrate number is 1.0, the clathrate number of the cyclic molecules is adjusted to fall within the above-mentioned range.

These cyclic molecules may be used alone or in combination of two or more kinds thereof.

The number of polymerizable functional groups of the polyrotaxane monomer (A) used in the present invention may be two or more in one molecule, and the polymerizable functional group is preferably contained in a cyclic molecule. By doing so, the sliding effect of the cyclic molecules, which is a feature of the polyrotaxane, can be sufficiently exhibited, and excellent mechanical properties can be exhibited.

In the polyrotaxane monomer (A) used in the present invention, it is preferable that a side chain is introduced into the above-described cyclic molecule in consideration of adjustment of compatibility with the polymerizable monomer (B) in order to express more excellent characteristics.

Furthermore, when the polyrotaxane monomer (A) has a side chain, the side chain preferably has a polymerizable functional group. By doing so, since it is bonded to the polymerizable monomer (B) via the side chain, it is possible to express more excellent characteristics.

The side chain is not particularly limited, but is preferably formed by repetition of an organic chain having 3 to 20 carbon atoms. In addition, those having different kinds of side chains or different number average molecular weights may be introduced into the cyclic molecule. The number average molecular weight of such a side chain is in a range of 45 to 10,000, preferably 55 to 5,000, and more preferably 100 to 1,500. The number average molecular weight of the side chain can be adjusted by the amount of a substance used at the time of introducing the side chain, and can be determined by calculation. In addition, when it is determined from the obtained polyrotaxane monomer (A), it can be determined from ¹H-NMR measurement.

When the side chain is too short (when the molecular weight of the side chain is too small), the compatibility with the other polymerizable monomer (B) tends to decrease. In addition, if the side chain is too short, when a polymerizable functional group is introduced into the side chain, the mechanical properties of the resulting cured body tend to decrease, and the effect exhibited in the cured body tends to decrease. On the other hand, if the side chain is too long, the viscosity increases when mixed with the polymerizable monomer (B), and the appearance of the cured body tends to be poor, and the hardness and wear resistance of the cured body tend to decrease.

The side chain is usually introduced by utilizing a reactive functional group of the cyclic molecule and modifying the reactive functional group. Among them, in the present invention, the polyrotaxane monomer (A) in which the cyclic molecule has a hydroxy group and the hydroxy group is modified to introduce a side chain is preferable. For example, α-cyclodextrin ring has 18 hydroxy groups as reactive functional groups. The hydroxy group may be modified to introduce a side chain. That is, a maximum of 18 side chains can be introduced into one α-cyclodextrin ring.

In order to sufficiently exhibit the function of the side chain, 4 to 70% (hereinafter, this value is also referred to as a degree of modification) of the total number of reactive functional groups possessed by the cyclic molecule is preferably modified with the side chain. The degree of modification is an average value.

As will be described in detail below, the reactive functional group (for example, a hydroxy group) of the cyclic molecule has lower reactivity than the reactive functional group (for example, a hydroxy group) of the side chain. Therefore, even if the degree of modification is not 100%, more excellent effects can be exhibited as long as the degree of modification is within the above range.

In the present invention, when a hydroxy group corresponds to a polymerizable functional group, it is considered as follows. For example, when the cyclic molecule is a cyclodextrin ring, a hydroxy group in which a side chain is not introduced among hydroxy groups of the cyclodextrin ring is also regarded as a polymerizable functional group. Incidentally, when side chains are bonded to 9 of the 18 OH groups of the α-cyclodextrin ring, the degree of modification is 50%.

In the present invention, the side chain may be linear or branched as long as the molecular weight is within the above-mentioned range. For the introduction of the side chain, a known method, for example, a method or a compound disclosed in WO2015/159875 may be appropriately used. Specifically, ring-opening polymerization; radical polymerization; cationic polymerization; anionic polymerization; living radical polymerization such as atom transfer radical polymerization, RAFT polymerization, and NMP polymerization; and the like can be used. By reacting an appropriately selected compound with the reactive functional group of the cyclic molecule by the above method, a side chain having an appropriate size can be introduced.

For example, by ring-opening polymerization, a side chain derived from a cyclic compound such as a cyclic ether, a cyclic siloxane, a cyclic lactone, a cyclic lactam, a cyclic acetal, a cyclic amine, a cyclic carbonate, a cyclic iminoether, or a cyclic thiocarbonate can be introduced.

Among the cyclic compounds, a cyclic ether, a cyclic lactone, and a cyclic lactam are preferably used from the viewpoint of high reactivity and easy adjustment of the size (molecular weight).

In the side chain introduced by the ring-opening polymerization of a cyclic compound such as a cyclic lactone or a cyclic ether, a hydroxy group is introduced at the terminal of the side chain, and in the side chain introduced by the ring-opening polymerization of a cyclic lactam, an amino group is introduced at the terminal of the side chain. Suitable cyclic ethers and cyclic lactones are disclosed in WO2015/159875.

In the present invention, preferable cyclic lactams include 4-membered ring lactams such as 4-benzoyloxy-2-azetidinone, 5-membered ring lactams such as γ-butyrolactam, 2-azabicyclo(2,2,1)hept-5-en-3-one, and 5-methyl-2-pyrrolidone, 6-membered ring lactams such as ethyl 2-piperidone-3-carboxylate, 7-membered ring lactams such as ε-caprolactum and DL-α-amino-ε-caprolactum, and ω-heptalactam.

These cyclic compounds may be used alone or in combination of two or more kinds thereof.

In the present invention, the side chain introduction compound suitably used is a lactone compound or a lactam compound, particularly suitable lactone compounds are lactone compounds such as ε-caprolactone, α-acetyl-γ-butyrolactone, α-methyl-γ-butyrolactone, γ-valerolactone, γ-butyrolactone, and the like, particularly suitable lactam compounds are ε-caprolactam, γ-butyrolactam, and DL-α-amino-ε-caprolactam, and most preferred are ε-caprolactone and ε-caprolactam.

In addition, when a cyclic compound is reacted by ring-opening polymerization to introduce a side chain, a reactive functional group (for example, a hydroxy group) of a cyclic molecule is poor in reactivity, and it may be difficult to directly react a large molecule particularly due to steric hindrance or the like. In such a case, for example, in order to react with the above-mentioned caprolactone or the like, a low molecular weight compound such as propylene oxide is once reacted with the reactive functional group of the cyclic molecule to effect hydroxypropylation, thereby introducing a functional group having high reactivity. Thereafter, a means of introducing a side chain by ring-opening polymerization using the above-mentioned cyclic compound can be adopted. In this case, the hydroxypropylated moiety can also be regarded as a side chain.

In addition, a side chain having a group having active hydrogen (active hydrogen-containing group) can be introduced by introducing a side chain derived from a cyclic compound such as the above-mentioned cyclic acetal, cyclic amine, cyclic carbonate, cyclic iminoether, or cyclic thiocarbonate by ring-opening polymerization. Specific examples of these cyclic compounds are those described in WO2015/068798.

A method for introducing a side chain into a cyclic molecule by radical polymerization is as follows. The cyclic molecule may not have an active site serving as a radical initiation point. In this case, prior to the reaction of a radical polymerizable compound, it is necessary to react a compound for forming a radical initiation point with a functional group (for example, a hydroxy group) of the cyclic molecule to form an active site serving as a radical initiation point.

As the compound for forming such a radical initiation point, an organic halogen compound is representative. Examples thereof include 2-bromoisobutyryl bromide, 2-bromobutyric acid, 2-bromopropionic acid, 2-chloropropionic acid, 2-bromoisobutyric acid, epichlorohydrin, epibromohydrin, and 2-chloroethyl isocyanate. That is, these organic halogen compounds are bonded to a cyclic molecule by a reaction with a functional group of the cyclic molecule, and a group containing a halogen atom (organic halogen compound residue) is introduced into the cyclic molecule. In this organic halogen compound residue, a radical is generated by the transfer of a halogen atom or the like during radical polymerization, and this radical serves as a radical polymerization initiation point to allow radical polymerization to proceed.

The above-mentioned organic halogen compound residue can also be introduced, for example, by reacting a compound having a functional group such as amine, isocyanate or imidazole with a hydroxy group of the cyclic molecule to introduce a functional group other than the hydroxy group, and reacting the above-mentioned organic halogen compound with such other functional group.

As the radical polymerizable compound used for introducing a side chain by radical polymerization, a compound having at least one group having an ethylenically unsaturated bond, for example, at least one functional group such as a (meth)acrylate group, a vinyl group or a styryl group (hereinafter also referred to as an ethylenically unsaturated monomer) is preferably used. As the ethylenically unsaturated monomer, an oligomer or a polymer having a terminal ethylenically unsaturated bond (hereinafter referred to as a macromonomer) can also be used. As such an ethylenically unsaturated monomer, specific examples of suitable ethylenically unsaturated monomers include those described in WO2015/068798.

In the present invention, a reaction in which a functional group of a side chain is reacted with another compound to introduce a structure derived from the other compound may be referred to as “modification”. The compound used for modification may be any compound capable of reacting with the functional group of the side chain. By selecting the compound, various polymerizable functional groups can be introduced into the side chain, or the side chain can be modified to a non-polymerizable group.

As understood from the above description, the side chain introduced into the cyclic molecule may have various functional groups in addition to the polymerizable functional group.

Further, depending on the kind of the functional group contained in the compound used for introducing the side chain, a part of this side chain may be bonded to a functional group of a ring of a cyclic molecule contained in another axis molecule to form a crosslinked structure.

As described above, the polymerizable functional group of the polyrotaxane monomer (A) is preferably a group contained in the cyclic molecule or a group contained in the side chain introduced into the cyclic molecule. Among them, in consideration of reactivity, the terminal of the side chain is preferably a polymerizable functional group, and two or more polymerizable functional groups introduced into the terminal of the side chain may be introduced per molecule of the polyrotaxane monomer (A). Although the upper limit of the number of polymerizable functional groups is not particularly limited, the upper limit of the number of polymerizable functional groups is preferably such that the value obtained by dividing the number of moles of the polymerizable functional group introduced into the terminal of the side chain by the weight average molecular weight (Mw) of the polyrotaxane monomer (A) (hereinafter, also referred to as polymerizable functional group content) is 10 mmol/g or less. As described above, the polymerizable functional group content is a value obtained by dividing the number of moles of the polymerizable functional group introduced into the terminal of the side chain by the weight average molecular weight (Mw) of the polyrotaxane monomer (A). In other words, the polymerizable functional group content refers to the number of moles of the polymerizable functional group introduced into the terminal of the side chain per 1 g of the polyrotaxane monomer (A).

The polymerizable functional group content is preferably 0.2 to 8 mmol/g, and particularly preferably 0.5 to 5 mmol/g. The weight average molecular weight is a value measured by a gel permeation chromatography (GPC) described in Examples described later.

A total polymerizable functional group content of the polymerizable functional group not introduced into the side chain and the polymerizable functional group introduced into the side chain is preferably in the following range. To be specific, the total polymerizable functional group content is preferably 0.2 to 20 mmol/g. The total polymerizable functional group content is more preferably 0.4 to 16 mmol/g, and particularly preferably 1 to 10 mmol/g. The total polymerizable functional group content is a value obtained by dividing the sum of the number of moles of the polymerizable functional group not introduced into the side chain and the number of moles of the polymerizable functional group introduced into the side chain by the weight average molecular weight (Mw) of the polyrotaxane monomer (A).

The numbers of moles of the polymerizable functional groups and the total polymerizable functional groups described above are average values.

The polymerizable functional group is not particularly limited as long as it can be polymerized with the polymerizable monomer (B). Among them, in the present invention, a preferable polymerizable functional group is at least one active hydrogen group selected from the group consisting of a hydroxy group, an amino group, and a thiol group. By having these polymerizable functional groups, the polyrotaxane monomer (A) can be introduced into a urethane (urea) resin to be described later.

In the description herein, the urethane (urea) resin refers to a resin containing at least one bond selected from the group consisting of a urethane bond, a thiourethane bond, a urea bond, and a thiourea bond.

In the present invention, the polyrotaxane monomer (A) most preferably used is one in which polyethylene glycol bonded to both terminals by adamantyl groups is used as an axis molecule, α-cyclodextrin rings are used as cyclic molecules, and side chains (OH groups at the terminals) are introduced into the rings by polycaprolactone.

In this case, the side chain may be introduced by hydroxypropylation of the hydroxy group of the α-cyclodextrin ring followed by ring-opening polymerization of ε-caprolactone.

All the terminals of the introduced side chains may be hydroxy groups, or they may be modified to non-reactive groups so as to have a desired number of moles of hydroxy groups.

<(B) Polymerizable Monomer Other than Polyrotaxane Monomer (A) having at Least Two Polymerizable Functional Groups in a Molecule>

In the present invention, the polymerizable monomer (B) other than the polyrotaxane monomer (A) is not particularly limited as long as it is a compound having a group capable of reacting (polymerizing) with the polymerizable functional group of the polyrotaxane monomer (A). As a matter of course, the polymerizable monomer (B) is a compound other than the polyrotaxane monomer (A).

As the polymerizable monomer (B), a known compound can be used without any limitation as long as it is a polymerizable monomer that can be polymerized with the polyrotaxane monomer (A). As described above, various polymerizable functional groups can be introduced into the polyrotaxane monomer (A). The polymerizable monomer (B) may be selected in accordance with the introduction of the polymerizable functional groups into the polyrotaxane monomer (A). Examples thereof include polymerizable monomers described in WO2015/068798.

In the present invention, for example, when the polymerizable functional group contained in the polyrotaxane monomer (A) has a polymerizable functional group selected from a hydroxy group, a thiol group, and an amino group (the amino group of the present invention refers to both a primary amino group (—NH₂) and a secondary amino group (—NHR; wherein R represents a substituent, for example, an alkyl group)), the polymerizable monomer (B) may include (B1) an iso(thio)cyanate compound having at least two iso(thio)cyanate groups in the molecule (hereinafter simply referred to as “iso(thio)cyanate compound (B1)” or “component (B1)”).

In addition, when the polymerizable functional group contained in the polyrotaxane monomer (A) is a hydroxy group or an amino group, (B2) an epoxy group-containing monomer having an epoxy group (hereinafter also simply referred to as “epoxy group-containing monomer (B2)” or “component (B2)”) can also be selected as the polymerizable monomer (B).

On the other hand, when the polymerizable functional group contained in the polyrotaxane monomer (A) is an isocyanate group or an isothiocyanate group, the polymerizable monomer (B) can be selected from (B3) a (thi)ol compound having at least two groups selected from a hydroxy group and a thiol group (hereinafter also simply referred to as “(thi)ol compound (B3)” or “component (B3)”) and (B4) an amino group-containing monomer having at least two amino groups (hereinafter also simply referred to as “amino group-containing monomer (B4)” or “component (B4)”).

In the present invention, as long as the polymerizable composition contains the polyrotaxane monomer (A) and the polymerizable monomer (B), the polymerizable composition may contain other components within a range not impairing the effects of the present invention. For example, the polymerizable composition may contain other polymerizable monomers which are not polymerized with the polyrotaxane monomer (A). Specifically, when the polymerization reaction is a sequential addition (for example, polycondensation/polyaddition) reaction, a polymerizable composition containing the component (A) and the polymerizable monomer (B) which can be polymerized with the component (A) is allowed to contain another polymerizable monomer which is not polymerized with the component (A) but is polymerized with the polymerizable monomer (B), whereby the component (A), the component (B) and the other polymerizable monomer can be copolymerized. That is, in the case of the sequential addition reaction, the polymerizable composition may contain not only the component (A) and the polymerizable monomer (B) capable of polymerizing with the component (A) but also other polymerizable monomers that can be copolymerized. Of course, the polymerizable composition may be composed only of the component (A) and the polymerizable monomer (B) capable of polymerizing with the component (A).

Examples of the sequential addition reaction will now be described in more detail. Specifically, for example, in a case where the polymerizable functional group contained in the polyrotaxane monomer (A) is an active hydrogen-containing group such as a hydroxy group, if the polymerizable composition contains the iso(thio)cyanate compound (B1) as the polymerizable monomer (B), the polymerizable composition may also contain the (thi)ol compound (B3) and the amino group-containing monomer (B4). In the case of the sequential addition reaction, since the component (B1) is contained, a resin in which the component (A), the component (B1), the component (B3), and/or the component (B4) are copolymerized can be obtained. As a matter of course, in this case, the polymerizable composition may contain the component (B2). The polymerizable composition may be composed of the component (A) and the component (B1) capable of polymerizing with the component (A).

In the case of the sequential addition reaction, it is preferable to separately store each component (component (A) and each polymerizable monomer) to be reacted with each other before polymerization.

When the polymerizable functional group contained in the polyrotaxane monomer (A) is a radical polymerizable group, the polymerizable composition contains a monomer having a radical polymerizable group. Since radical polymerization is chain polymerization, unlike sequential addition reaction, all of the polymerizable monomers contained in the polymerizable composition are monomers having a radical polymerizable group. Specifically, the polymerizable monomer (B) is preferably selected from (meth)acrylate compounds having a (meth)acrylate group and allyl compounds as (B5) a radical polymerizable monomer to be described in detail below (hereinafter also referred to as component (B)), and is particularly preferably selected from (meth)acrylate compounds.

As described above, the case of the sequential addition reaction and the case of the chain polymerization have been described, but in the case where both of them can be performed, the following method may be employed.

For example, when the polymerizable functional group contained in the polyrotaxane monomer (A) has both an active hydrogen-containing group such as a hydroxy group and a radical polymerizable group, the polymerizable monomer (B) may be only a (meth)acrylate compound having a (meth)acrylate group, an allyl compound, or the like, or when the polymerizable monomer (B) contains the component (B1), the polymerizable monomer (B) may further contain the components (B2), (B3), (B4), and/or (B5).

Hereinafter, the polymerizable monomer (B) will be individually described in detail.

### <(B1) Iso(thio)cyanate Compound; Component (B1)>

The iso(thio)cyanate compound (B1) is a compound having at least two groups selected from the group consisting of an isocyanate group and an isothiocyanate group. Of course, compounds having two groups, an isocyanate group and an isothiocyanate group, may also be selected. Among them, a compound having 2 to 6 iso(thio)cyanate groups in the molecule is preferable, a compound having 2 to 4 iso(thio)cyanate groups is more preferable, and a compound having 2 or 3 iso(thio)cyanate groups is still more preferable.

The iso(thio)cyanate compound (B1) may be (B12) a urethane prepolymer (hereinafter also referred to as component (B12)) produced by the reaction of (B13) a bifunctional iso(thio)cyanate compound (hereinafter also referred to as component (B13)) having two groups selected from the group consisting of isocyanate groups and isothiocyanate groups in the molecule and (B32) a bifunctional active hydrogen-containing compound (hereinafter also referred to as component (B32)) having two active hydrogen-containing groups in the molecule. As the urethane prepolymer (B12) corresponding to the component (B1), a generally used one containing two or more unreacted isocyanate groups or isothiocyanate groups can be used in the present invention without any limitation, and a urethane prepolymer (B12) containing two or more isocyanate groups is preferable.

The active hydrogen-containing group in the component (B32) is a group selected from a hydroxy group, a thiol group, and an amino group. Specific examples of the component (B32) include those exemplified in “(B3) (thi)ol compound” or “(B4) amino group-containing monomer” to be described in detail below.

The iso(thio)cyanate compound (B1) can be roughly classified into aliphatic isocyanates, alicyclic isocyanates, aromatic isocyanates, isothiocyanates, other isocyanates, and urethane prepolymers (B12). As the component (B1), one type of compound may be used, or a plurality of types of compounds may be used. When a plurality of types of compounds are used, the reference mass is the total amount of the plurality of types of compounds. Specific examples of the component (B1) include the following.

### [Aliphatic Isocyanate; Component (B1)]

Bifunctional isocyanates such as ethylene diisocyanate, trimethylene diisocyanate, tetramethylene diisocyanate, hexamethylene diisocyanate, octamethylene diisocyanate, nonamethylene diisocyanate, 2,2′-dimethylpentane diisocyanate, 2,2,4-trimethylhexamethylene diisocyanate, decamethylene diisocyanate, butenediisocyanate, 1,3-butadiene-1,4-diisocyanate, 2,4,4-trimethylhexamethylene diisocyanate, 1,6,11-trimethylundecamethylene diisocyanate, 1,3,6-trimethylhexamethylene diisocyanate, 1,8-diisocyanate-4-isocyanatomethyloctane, 2,5,7-trimethyl-1,8-diisocyanate-5-isocyanatomethyloctane, bis(isocyanatoethyl) carbonate, bis(isocyanatoethyl) ether, 1,4-butylene glycol dipropyl ether-ω,ω′-diisocyanate, lysine diisocyanate methyl ester, and 2,4,4-trimethylhexamethylene diisocyanate (corresponding to the component (B13) constituting the urethane prepolymer (B12) described in detail below).

### [Alicyclic Isocyanate; Component (B1)]

Bifunctional isocyanates such as isophorone diisocyanate, (bicyclo[2.2.1]heptane-2,5-diyl)bismethylene diisocyanate, (bicyclo[2.2.1]heptane-2,6-diyl)bismethylene diisocyanate, 2β,5α-bis(isocyanato)norbornane, 2β,5β-bis(isocyanato)norbornane, 2β,6α-bis(isocyanato)norbornane, 2β,6β-bis(isocyanato)norbornane, 2,6-di(isocyanatomethyl)furan, bis(isocyanatomethyl)cyclohexane, dicyclohexylmethane-4,4′-diisocyanate, 4,4-isopropylidenebis(cyclohexylisocyanate), cyclohexane diisocyanate, methylcyclohexane diisocyanate, dicyclohexyldimethylmethane diisocyanate, 2,2′-dimethyldicyclohexylmethane diisocyanate, bis(4-isocyanate-n-butylidene)pentaerythritol, dimer acid diisocyanate, 2,5-bis(isocyanatomethyl)-bicyclo[2,2,1]-heptane, 2,6-bis(isocyanatomethyl)-bicyclo[2,2,1]-heptane, 3,8-bis(isocyanatemethyl)tricyclodecane, 3,9-bis(isocyanatemethyl)tricyclodecane, 4,8-bis(isocyanatemethyl)tricyclodecane, 4,9-bis(isocyanatemethyl)tricyclodecane, 1,5-diisocyanatodecalin, 2,7-diisocyanatodecalin, 1,4-diisocyanatodecalin, 2,6-diisocyanatodecalin, bicyclo[4.3.0]nonane-3,7-diisocyanate, bicyclo[4.3.0]nonane-4,8-diisocyanate, bicyclo[2.2.1]heptane-2,5-diisocyanate, bicyclo[2.2.1]heptane-2,6-diisocyanate, bicyclo[2,2,2]octane-2,5-diisocyanate, bicyclo[2,2,2]octane-2,6-diisocyanate, tricyclo[5.2.1.0^{2.6}]decane-3,8-diisocyanate, and tricyclo[5.2.1.0^{2.6}]decane-4,9-diisocyanate (corresponding to the component (B13) constituting the urethane prepolymer (B12) described in detail below).

Polyfunctional isocyanates such as 2-isocyanatomethyl-3-(3-isocyanatopropyl)-5-isocyanatomethyl-bicyclo[2,2,1]-heptane, 2-isocyanatomethyl-3-(3-isocyanatopropyl)-6-isocyanatomethyl-bicyclo[2,2,1]-heptane, 2-isocyanatomethyl-2-(3-isocyanatopropyl)-5-isocyanatomethyl-bicyclo[2,2,1]-heptane, 2-isocyanatomethyl-2-(3-isocyanatopropyl)-6-isocyanatomethyl-bicyclo[2,2,1]-heptane, 2-isocyanatomethyl-3-(3-isocyanatopropyl)-5-(2-isocyanatoethyl)-bicyclo[2,2,1]-heptane, 2-isocyanatomethyl-3-(3-isocyanatopropyl)-6-(2-isocyanatoethyl)-bicyclo[2,1,1]-heptane, 2-isocyanatomethyl-2-(3-isocyanatopropyl)-5-(2-isocyanatoethyl)-bicyclo[2,2,1]-heptane, 2-isocyanatomethyl-2-(3-isocyanatopropyl)-6-(2-isocyanatoethyl)-bicyclo[2,2,1]-heptane, and 1,3,5-tris(isocyanatomethyl)cyclohexane.

### [Aromatic Isocyanate; Component (B1)]

Bifunctional isocyanates such as xylylene diisocyanate (o-, m-, p-), tetrachloro-m-xylylene diisocyanate, methylenediphenyl-4,4′-diisocyanate, 4-chloro-m-xylylene diisocyanate, 4,5-dichloro-m-xylylene diisocyanate, 2,3,5,6-tetrabromo-p-xylylene diisocyanate, 4-methyl-m-xylylene diisocyanate, 4-ethyl-m-xylylene diisocyanate, bis(isocyanatoethyl)benzene, bis(isocyanatopropyl)benzene, 1,3-bis(α,α-dimethylisocyanatomethyl)benzene, 1,4-bis(α,α-dimethylisocyanatomethyl)benzene, α,α,α′,α′-tetramethylxylylene diisocyanate, bis(isocyanatobutyl)benzene, bis(isocyanatomethyl)naphthalene, bis(isocyanatomethyl)diphenyl ether, bis(isocyanatoethyl)phthalate, 2,6-di(isocyanatomethyl)furan, phenylene diisocyanate (o-, m-, p-), tolylene diisocyanate, ethylphenylene diisocyanate, isopropylphenylene diisocyanate, dimethylphenylene diisocyanate, diethylphenylene diisocyanate, diisopropylphenylene diisocyanate, trimethylbenzene triisocyanate, benzene triisocyanate, 1,3,5-triisocyanate methylbenzene, 1,5-naphthalene diisocyanate, methylnaphthalene diisocyanate, biphenyl diisocyanate, 2,4-tolylene diisocyanate, 2,6-tolylene diisocyanate, 4,4′-diphenylmethane diisocyanate, 2,2′-diphenylmethane diisocyanate, 2,4′-diphenylmethane diisocyanate, 3,3-dimethyldiphenylmethane-4,4′-diisocyanate, bibenzyl-4,4′-diisocyanate, bis(isocyanatophenyl)ethylene, 3,3′-dimethoxybiphenyl-4,4′-diisocyanate, phenyl isocyanatomethyl isocyanate, phenyl isocyanatoethyl isocyanate, tetrahydronaphthylene diisocyanate, hexahydrobenzene diisocyanate, hexahydrodiphenylmethane-4,4′-diisocyanate, diphenyletherdiisocyanate, ethyleneglycoldiphenyletherdiisocyanate, 1,3-propyleneglycoldiphenyletherdiisocyanate, benzophenonediisocyanate, diethyleneglycoldiphenyletherdiisocyanate, dibenzofurandiisocyanate, carbazolediisocyanate, ethylcarbazolediisocyanate, dichlorocarbazolediisocyanate, 2,4-tolylenediisocyanate, and 2,6-tolylenediisocyanate (corresponding to the component (B13) constituting the urethane prepolymer (B12) described in detail below).

Polyfunctional isocyanate compounds such as methylene triisocyanate, triphenylmethane triisocyanate, polymeric MDI, naphthalene triisocyanate, diphenylmethane-2,4,4′-triisocyanate, 3-methyldiphenylmethane-4,4′,6-triisocyanate, and 4-methyldiphenylmethane 2,3,4′,5,6-pentaisocyanate.

### [Isothiocyanate; Component (B1)]

Bifunctional isothiocyanates such as p-phenylenediisothiocyanate, xylylene-1,4-diisothiocyanate, and ethylidine diisothiocyanate (corresponding to the component (B13) constituting the urethane prepolymer (B12) described in detail below).

### [Other Isocyanates: Component (B1)]

Examples of other isocyanates include polyfunctional isocyanates having a biuret structure, a uretdione structure, or an isocyanurate structure (for example, JP 2004-534870 A discloses a method for modifying a biuret structure, a uretdione structure, or an isocyanurate structure of an aliphatic polyisocyanate) using diisocyanates such as hexamethylene diisocyanate or tolylene diisocyanate as a main raw material, and polyfunctional compounds as adducts with trifunctional or higher polyols such as trimethylolpropane (disclosed in a book (Polyurethane Resin Handbook, edited by Keiji Iwata, Nikkan Kogyo Shimbun, Ltd. (1987)).

[(B12) Urethane Prepolymer; Component (B1) having iso(thio)cyanate Groups at Both Terminals]

In the present invention, a urethane prepolymer (B12) produced by the reaction of the above-mentioned component (B13) with a bifunctional active hydrogen-containing compound (B32) having two active hydrogen-containing groups in the molecule to be described later can also be used as the component (B1).

The urethane prepolymer (B12) is not particularly limited, but it is particularly preferable to use the following exemplified monomers as the component (B13). Specifically, it is preferable to use 1,5-naphthalene diisocyanate, xylene diisocyanate (o-, m-, p-), 2,4-tolylene diisocyanate, 2,6-tolylene diisocyanate, phenylene diisocyanate (o-, m-, p-), 2,2′-diphenylmethane diisocyanate, 2,4′-diphenylmethane diisocyanate, 4,4′-diphenylmethane diisocyanate, isophorone diisocyanate, 1,3-bis(isocyanatomethyl)cyclohexane, dicyclohexylmethane-4,4′-diisocyanate, or (bicyclo[2.2.1]heptane-2,5(2,6)-diyl)bismethylene diisocyanate. These are preferably reacted with a bifunctional active hydrogen-containing compound (B32) to obtain a component (B12) having an isocyanate group and/or an isothiocyanate group at both terminals.

In order for the resin finally obtained to exhibit particularly excellent characteristics, it is preferable to produce the urethane prepolymer (B12) using at least one kind of the bifunctional active hydrogen-containing compound (B32) having a molecular weight (number average molecular weight) of 300 to 2000. The active hydrogen-containing group refers to a hydroxy group, a thiol group, or an amino group. Among them, in consideration of reactivity, the active hydrogen-containing group in the bifunctional active hydrogen-containing compound (B32) is preferably a hydroxy group.

The bifunctional active hydrogen-containing compounds (B32) having a molecular weight (number average molecular weight) of 300 to 2000 may be used in combination of different types or different molecular weights. In addition, in order to adjust the hardness and the like of the finally obtained resin, the component (B32) having a molecular weight (number average molecular weight) of 300 to 2000 and the component (B32) having a molecular weight (number average molecular weight) of 90 to 300 can be used in combination when forming the urethane prepolymer (B12). In this case, although it depends on the type of the component (B32) and the bifunctional iso(thio)cyanate compound component (B13) to be used and the amount of the component, it is preferable that when the component (B32) having a molecular weight of 300 to 2000 is 100 parts by mass, the component (B32) having a molecular weight of 90 to 300 is 0 to 50 parts by mass. Further, it is preferable that the component (B32) having a molecular weight of 90 to 300 be 1 to 40 parts by mass.

In addition, the urethane prepolymer (B12) must have an isocyanate group and/or an isothiocyanate group at both molecular terminals. Therefore, the urethane prepolymer (B12) is preferably produced so that the total number of moles (n5) of the isocyanate group and/or isothiocyanate group in the bifunctional iso(thio)cyanate compound (B13) and the total number of moles (n6) of the active hydrogen-containing group (a hydroxy group, a thiol group, or an amino group) in the bifunctional active hydrogen-containing compound (B32) satisfy 1<(n5)/(n6)≤2.3. When using two or more types of the component (B13) at the molecular terminals, the number of moles (n5) of the isocyanate group and/or isothiocyanate group is, of course, the total number of moles of the isocyanate group and/or isothiocyanate group of the component (B13). Further, the number of moles (n6) of active hydrogen-containing groups of two or more kinds of the bifunctional active hydrogen-containing compounds (B32) is, of course, the number of moles of active hydrogens in the total of active hydrogen-containing groups. Even when the active hydrogen-containing group is a primary amino group, the primary amino group is considered to be 1 mol. That is, in the primary amino group, considerable energy is required for the second amino group (—NH) to react (even in the case of the primary amino group, the second —NH is difficult to react). Therefore, in the present invention, even if a bifunctional active hydrogen-containing compound (B32) having a primary amino group is used, the primary amino group can be calculated as 1 mol.

The iso(thio)cyanate equivalent (the total amount of the isocyanate equivalent and/or the isothiocyanate equivalent) of the urethane prepolymer (B12) can be determined by quantifying the isocyanate group and/or the isothiocyanate group contained in the urethane prepolymer (B12) in accordance with JIS K 7301. The isocyanate group and/or isothiocyanate group can be quantified by the following back titration method. First, the obtained urethane prepolymer (B12) is dissolved in a dried solvent. Next, di-n-butylamine, which is clearly in excess of the amount of isocyanate groups and/or isothiocyanate groups contained in the urethane prepolymer (B12) and has a known concentration, is added to the dried solvent, and the total isocyanate groups and/or isothiocyanate groups of the urethane prepolymer (B12) are reacted with di-n-butylamine. The amount of di-n-butylamine consumed is then determined by titration with acid of the di-n-butylamine not consumed (not participating in the reaction). Since the consumed di-n-butylamine and the isocyanate group and/or isothiocyanate group contained in the urethane prepolymer (B12) are in the same amount, the iso(thio)cyanate equivalent can be determined. Since the urethane prepolymer (B12) is a linear urethane prepolymer having an isocyanate group and/or an isothiocyanate group at both terminals, the number average molecular weight of the urethane prepolymer (B12) is twice as large as the iso(thio)cyanate equivalent. The molecular weight of the urethane prepolymer (B12) tends to match the value measured by gel permeation chromatography (GPC). For example, when the urethane prepolymer (B12) and the bifunctional iso(thio)cyanate compound (B13) are used in combination, a mixture of both may be measured according to the above-mentioned method.

The urethane prepolymer (B12) is not particularly limited, but preferably has an iso(thio)cyanate equivalent of 300 to 5000, more preferably 350 to 3000, and particularly preferably 350 to 2000. The reason for this is not particularly clear, but is considered as follows. That is, it is considered that when the urethane prepolymer (B12) having a certain degree of molecular weight reacts with the polymerizable functional group of the polyrotaxane monomer (A), the size of the slidable molecule becomes large and the movement of the molecule itself becomes large, and as a result, recovery from deformation (elastic recovery; low hysteric) becomes easy. Furthermore, it is considered that by using the urethane prepolymer (B12), crosslinking points in the resin are easily dispersed and are present randomly and uniformly, and stable performances are exhibited. It is considered that the resin obtained by using the urethane prepolymer (B12) can be easily controlled at the time of production and can be suitably used as a polishing pad. It is also considered that such an effect is exhibited even when the average iso(thio)cyanate equivalent of the polyiso(thio)cyanate compound is 300 to 5000 in the case where the urethane prepolymer (B12) and the bifunctional iso(thio)cyanate compound (B13) are used in combination. However, it is considered that the effect is more remarkable in the case of using only the urethane prepolymer (B12).

The urethane prepolymer (B12) used in the present invention may be produced by reacting a bifunctional active hydrogen-containing compound (B32) having two active hydrogen-containing groups in a molecule such as a hydroxy group, an amino group, or a thiol group with a bifunctional iso(thio)cyanate compound (B13) to produce a urethane prepolymer (B12) having an isocyanate group or an isothiocyanate group at its molecular terminal. There is no limitation as long as a prepolymer having an isocyanate group or an isothiocyanate group at a terminal can be obtained.

As described above, preferable blending amounts of the bifunctional active hydrogen-containing compound (B32) and the bifunctional iso(thio)cyanate compound (B13) for obtaining the urethane prepolymer (B12) are as follows. To be more specific, it is preferable that the urethane prepolymer (B12) is produced so that the number of moles (n5) of the isocyanate group or isothiocyanate group in the component (B13) and the number of moles (n6) of the active hydrogen in the bifunctional active hydrogen-containing compound (B32) satisfy 1<(n5)/(n6)≤2.3.

In addition, in the reaction for producing the urethane prepolymer, the urethane prepolymer can be produced by heating or adding a urethanization catalyst as necessary.

Most preferred examples of the component (B1) used in the present invention include alicyclic isocyanates such as isophorone diisocyanate, 1,3-bis(isocyanatemethyl)cyclohexane, and (bicyclo[2.2.1]heptane-2,5(2,6)-diyl)bismethylene diisocyanate; aromatic isocyanates such as 2,4-tolylene diisocyanate, 2,6-tolylene diisocyanate, 4,4′-diphenylmethane diisocyanate, and xylylene diisocyanate (o-, m-, p-); polyfunctional isocyanates having a biuret structure, a uretdione structure, or an isocyanurate structure, mainly composed of diisocyanates such as hexamethylene diisocyanate and tolylene diisocyanate; polyfunctional isocyanates as adducts with trifunctional or higher polyols; and urethane prepolymers (B12) from the view point of the strength of the resin to be formed and controlling the reactivity.

Among them, urethane prepolymer (B12) is particularly preferable.

### <(B2) Epoxy Group-Containing Monomer; Component (B2)>

The epoxy group-containing monomer has an epoxy group in the molecule as a polymerizable group, and is particularly suitable when a hydroxy group or an amino group is introduced as a polymerizable functional group of the polyrotaxane monomer (A).

Such an epoxy compound is roughly classified into an aliphatic epoxy compound, an alicyclic epoxy monomer, and an aromatic epoxy monomer, and as preferable specific examples thereof, those described in WO2015/068798 can be used.

### <(B3) (Thi)ol Compound; Component (B3)>

The (thi)ol compound (B3) is not particularly limited as long as it is a compound having at least two or more groups selected from the group consisting of a hydroxy group and a thiol group in one molecule. Of course, a compound having two groups, a hydroxy group and a thiol group, can also be selected.

The component (B3) is roughly classified into aliphatic alcohols, alicyclic alcohols, aromatic alcohols, polyesterpolyols, polyetherpolyols, polycaprolactonepolyols, polycarbonatepolyols, polyacrylpolyols, castor oil-based polyols, thiols, and OH/SH-type polymerizable group-containing monomers. Specific examples thereof include the following compounds.

### [Aliphatic Alcohol; Component (B3)]

Bifunctional polyols (corresponding to the bifunctional active hydrogen-containing compound (B32) constituting the urethane prepolymer (B12)) such as ethylene glycol, diethylene glycol, propylene glycol, dipropylene glycol, butylene glycol, 1,5-dihydroxypentane, 1,6-dihydroxyhexane, 1,7-dihydroxyheptane, 1,8-dihydroxyoctane, 1,9-dihydroxynonane, 1,10-dihydroxydecane, 1,11-dihydroxyundecane, 1,12-dihydroxydodecane, neopentyl glycol, glyceryl monooleate, monoelaidine, polyethylene glycol, 3-methyl-1,5-dihydroxypentane, dihydroxyneopentyl, 2-ethyl-1,2-dihydroxyhexane, and 2-methyl-1,3-dihydroxypropane.

Polyfunctional polyols such as glycerin, trimethylolethane, trimethylolpropane, ditrimethylolpropane, trimethylolpropane tripolyoxyethylene ether (for example, TMP-30, TMP-60, TMP-90 and the like manufactured by Nippon Nyukazai Co., Ltd.), butanetriol, 1,2-methylglucoside, pentaerythritol, dipentaerythritol, tripentaerythritol, sorbitol, erythritol, threitol, ribitol, arabinitol, xylitol, allitol, mannitol, dolcitol, iditol, glycol, inositol, hexanetriol, triglycerol, diglycerol, and triethylene glycol.

### [Alicyclic Alcohol; Component (B3)]

Bifunctional polyols (corresponding to the bifunctional active hydrogen-containing compound (B32) constituting the urethane prepolymer (B12)) such as hydrogenated bisphenol-A, cyclobutanediol, cyclopentanediol, cyclohexanediol, cycloheptanediol, cyclooctanediol, cyclohexanedimethanol, hydroxypropylcyclohexanol, tricyclo[5,2,1,0^{2,6}]decane-dimethanol, bicyclo[4,3,0]-nonanediol, dicyclohexanediol, tricyclo[5,3,1,1^{3,9}]dodecanediol, bicyclo[4,3,0]nonanedimethanol, tricyclo[5,3,1,1^{3,9}]dodecane-diethanol, hydroxypropyltricyclo[5,3,1,1^{3,9}]dodecanol, spiro[3,4]octanediol, butylcyclohexanediol, 1,1′-bicyclohexylidenediol, 1,4-cyclohexanedimethanol, 1,3-cyclohexanedimethanol, 1,2-cyclohexanedimethanol, and o-dihydroxyxylylene.

Polyfunctional polyols such as tris(2-hydroxyethyl)isocyanurate, cyclohexanetriol, sucrose, maltitol, and lactitol.

### [Aromatic Alcohol; Component (B3)]

Bifunctional polyols (corresponding to the bifunctional active hydrogen-containing compound (B32) constituting the urethane prepolymer (B12)) such as dihydroxynaphthalene, dihydroxybenzene, bisphenol A, bisphenol F, xylylene glycol, tetrabromobisphenol A, bis(4-hydroxyphenyl)methane, 1,1-bis(4-hydroxyphenyl)ethane, 1,2-bis(4-hydroxyphenyl)ethane, bis(4-hydroxyphenyl)phenylmethane, bis(4-hydroxyphenyl)diphenylmethane, bis(4-hydroxyphenyl)-1-naphthylmethane, 1,1-bis(4-hydroxyphenyl)-1-phenylethane, 2-(4-hydroxyphenyl)-2-(3-hydroxyphenyl)propane, 2,2-bis(4-hydroxyphenyl)butane, 1,1-bis(4-hydroxyphenyl)butane, 2,2-bis(4-hydroxyphenyl)-3-methylbutane, 2,2-bis(4-hydroxyphenyl)pentane, 3,3-bis(4-hydroxyphenyl)pentane, 2,2-bis(4-hydroxyphenyl)hexane, 2,2-bis(4-hydroxyphenyl)octane, 2,2-bis(4-hydroxyphenyl)-4-methylpentane, 2,2-bis(4-hydroxyphenyl)heptane, 4,4-bis(4-hydroxyphenyl)heptane, 2,2-bis(4-hydroxyphenyl)tridecane, 2,2-bis(4-hydroxyphenyl)octane, 2,2-bis(3-methyl-4-hydroxyphenyl)propane, 2,2-bis(3-ethyl-4-hydroxyphenyl)propane, 2,2-bis(3-n-propyl-4-hydroxyphenyl)propane, 2,2-bis(3-isopropyl-4-hydroxyphenyl)propane, 2,2-bis(3-sec-butyl-4-hydroxyphenyl)propane, 2,2-bis(3-tert-butyl-4-hydroxyphenyl)propane, 2,2-bis(3-cyclohexyl-4-hydroxyphenyl)propane, 2,2-bis(3-allyl-4′-hydroxyphenyl)propane, 2,2-bis(3-methoxy-4-hydroxyphenyl)propane, 2,2-bis(3,5-dimethyl-4-hydroxyphenyl)propane, 2,2-bis(2,3,5,6-tetramethyl-4-hydroxyphenyl)propane, bis(4-hydroxyphenyl)cyanomethane, 1-cyano-3,3-bis(4-hydroxyphenyl)butane, 2,2-bis(4-hydroxyphenyl)hexafluoropropane, 1,1-bis(4-hydroxyphenyl)cyclopentane, 1,1-bis(4-hydroxyphenyl)cyclohexane, 1,1-bis(4-hydroxyphenyl)cycloheptane, 1,1-bis(3-methyl-4-hydroxyphenyl)cyclohexane, 1,1-bis(3,5-dimethyl-4-hydroxyphenyl)cyclohexane, 1,1-bis(3,5-dichloro-4-hydroxyphenyl)cyclohexane, 1,1-bis(3-methyl-4-hydroxyphenyl)-4-methylcyclohexane, 1,1-bis(4-hydroxyphenyl)-3,3,5-trimethylcyclohexane, 2,2-bis(4-hydroxyphenyl)norbornane, 2,2-bis(4-hydroxyphenyl)adamantane, 4,4′-dihydroxydiphenyl ether, 4,4′-dihydroxy-3,3′-dimethyldiphenyl ether, ethylene glycol bis(4-hydroxyphenyl)ether, 4,4′-dihydroxydiphenyl sulfide, 3,3′-dimethyl-4,4′-dihydroxydiphenyl sulfide, 3,3′-dicyclohexyl-4,4′-dihydroxydiphenyl sulfide, 3,3′-diphenyl-4,4′-dihydroxydiphenyl sulfoxide, 4,4′-dihydroxydiphenyl sulfoxide, 3,3′-dimethyl-4,4′-dihydroxydiphenyl sulfoxide, 4,4′-dihydroxydiphenyl sulfone, 4,4′-dihydroxy-3,3′-dimethyldiphenyl sulfone, bis(4-hydroxyphenyl)ketone, bis(4-hydroxy-3-methylphenyl)ketone, 7,7′-dihydroxy-3,3′,4,4′-tetrahydro-4,4,4′,4′-tetramethyl-2,2′-spirobi(2H-1- benzopyran), trans-2,3-bis(4-hydroxyphenyl)-2-butene, 9,9-bis(4-hydroxyphenyl)fluorene, 3,3-bis(4-hydroxyphenyl)-2-butanone, 1,6-bis(4-hydroxyphenyl)-1,6-hexanedione, 4,4′-dihydroxybiphenyl, m-dihydroxyxylylene, p-dihydroxyxylylene, 1,4-bis(2-hydroxyethyl)benzene, 1,4-bis(3-hydroxypropyl)benzene, 1,4-bis(4-hydroxybutyl)benzene, 1,4-bis(5-hydroxypentyl)benzene, 1,4-bis(6-hydroxyhexyl)benzene, 2,2-bis[4-(2″-hydroxyethyloxy)phenyl]propane, hydroquinone, and resorcin.

Polyfunctional polyols such as trihydroxynaphthalene, tetrahydroxynaphthalene, benzenetriol, biphenyltetraol, pyrogallol, (hydroxynaphthyl)pyrogallol, and trihydroxyphenanthrene.

### [Polyester Polyol; Component (B3)]

Examples of the polyester polyol include a compound obtained by a condensation reaction between a polyol and a compound having a plurality of carboxylic acids. Among them, the number average molecular weight is preferably 400 to 2000, more preferably 500 to 1500, and most preferably 600 to 1200. The compound having hydroxy groups only at both terminals of the molecule (two in the molecule) corresponds to the bifunctional active hydrogen-containing compound (B32) constituting the urethane prepolymer (B12).

Here, examples of the polyol include ethylene glycol, 1,2-propanediol, 1,3-butanediol, 1,4-butanediol, 3-methyl-1,5-pentanediol, 1,6-hexanediol, 3,3′-dimethylolheptane, 1,4-cyclohexanedimethanol, neopentyl glycol, 3,3-bis(hydroxymethyl)heptane, diethylene glycol, dipropylene glycol, glycerin, and trimethylolpropane, and these may be used alone or in combination of two or more. Examples of the compound having a plurality of carboxylic acids include succinic acid, adipic acid, azelaic acid, sebacic acid, dodecanedicarboxylic acid, cyclopentanedicarboxylic acid, cyclohexanedicarboxylic acid, orthophthalic acid, isophthalic acid, terephthalic acid, and naphthalenedicarboxylic acid, and these may be used alone or in combination of two or more.

These polyester polyols are commercially available as reagents or industrially, and examples of commercially available products include “POLYLITE (registered trademark)” series manufactured by DIC Corporation, “Nippolan (registered trademark)” series manufactured by Nippon Polyurethane Industry Co., Ltd., “MAXIMOL (registered trademark)” series manufactured by Kawasaki Kasei Chemicals Ltd., and “Kuraray polyol (registered trademark)” series manufactured by Kuraray Co., Ltd.

### [Polyether Polyol; Component (B3)]

Examples of the polyether polyol include a compound obtained by ring-opening polymerization of an alkylene oxide or a reaction between a compound having two or more active hydrogen-containing groups in the molecule and an alkylene oxide, and a modified product thereof. Among them, the number average molecular weight is preferably 400 to 2000, more preferably 500 to 1500, and most preferably 600 to 1200. The compound having hydroxy groups only at both terminals of the molecule (two in the molecule) corresponds to the bifunctional active hydrogen-containing compound (B32) constituting the urethane prepolymer (B12).

Examples of the polyether polyol may include a polymer polyol, a urethane-modified polyether polyol, and a polyether ester copolymer polyol. Examples of the compound having two or more active hydrogen groups in the molecule include water and polyol compounds such as glycol and glycerin having one or more hydroxy groups in the molecule (such as ethylene glycol, propylene glycol, butanediol, glycerin, trimethylolpropane, hexanetriol, triethanolamine, diglycerol, pentaerythritol, trimethylolpropane, hexanetriol, and the like), and these may be used alone or in combination of two or more.

Examples of the alkylene oxide include cyclic ether compounds such as ethylene oxide, propylene oxide, and tetrahydrofuran, and these may be used alone or in combination of two or more.

Such polyetherpolyols are available as reagents or industrially, and examples of commercially available products include “EXCENOL (registered trademark)” series and “EMULSTAR (registered trademark)” manufactured by AGC Inc., and “Adeka polyether” series manufactured by ADEKA CORPORATION.

### [Polycaprolactone Polyol; Component (B3)]

Examples of the polycaprolactone polyol include compounds obtained by ring-opening polymerization of ε-caprolactone. Among them, the number average molecular weight is preferably 400 to 2000, more preferably 500 to 1500, and most preferably 600 to 1200. The compound having hydroxy groups only at both terminals of the molecule (two in the molecule) corresponds to the bifunctional active hydrogen-containing compound (B32) constituting the urethane prepolymer (B12).

These polycaprolactone polyols are available as reagents or industrially, and examples of commercially available products include “PLACCEL (registered trademark)” series manufactured by Daicel Corporation.

### [Polycarbonate Polyol; Component (B3)]

Examples of the polycarbonate polyol include compounds obtained by phosgenating one or more low molecular weight polyols, and compounds obtained by transesterification using ethylene carbonate, diethyl carbonate, diphenyl carbonate, or the like. Among them, the number average molecular weight is preferably 400 to 2000, more preferably 500 to 1500, and most preferably 600 to 1200. The compound having hydroxy groups only at both terminals of the molecule (two in the molecule) corresponds to the bifunctional active hydrogen-containing compound (B32) constituting the urethane prepolymer (B12).

Examples of the low molecular weight polyol include low molecular weight polyols such as ethylene glycol, 1,2-propanediol, 1,3-propanediol, 2-methyl-1,3-propanediol, 1,2-butanediol, 1,3-butanediol, 1,4-butanediol, 1,5-pentanediol, 1,6-hexanediol, 1,8-octanediol, 1,9-nonanediol, 1,10-decanediol, 3-methyl-1,5-pentanediol, 2-ethyl-4-butyl-1,3-propanediol, diethylene glycol, dipropylene glycol, neopentyl glycol, cyclohexane-1,4-diol, cyclohexane-1,4-dimethanol, dimer acid diol, ethylene oxide or propylene oxide adduct of bisphenol A, bis(β-hydroxyethyl)benzene, xylylene glycol, glycerin, trimethylolpropane, and pentaerythritol.

### [Polyacrylic Polyol; Component (B3)]

Examples of the polyacrylic polyol include polyol compounds obtained by polymerizing a (meth)acrylate acid ester or a vinyl monomer. The compound having hydroxy groups only at both terminals of the molecule (two in the molecule) corresponds to the bifunctional active hydrogen-containing compound (B32) constituting the urethane prepolymer (B12).

### [Castor Oil-Based Polyol; Component (B3)]

Examples of the castor oil-based polyol include polyol compounds using castor oil, which is a natural oil and fat, as a starting material. The compound having hydroxy groups only at both terminals of the molecule (two in the molecule) corresponds to the component (B32) constituting the urethane prepolymer (B12).

These castor oil polyols are available as reagents or industrially, and examples of commercially available products include “URIC (registered trademark)” series manufactured by Itoh Oil Chemicals Co., Ltd.

### [Thiol; Component (B3)]

As preferable specific examples of the thiol, those described in WO2015/068798 can be used. Among them, particularly preferable examples include the following.

Tetraethylene glycol bis(3-mercaptopropionate), 1,4-butanediol bis(3-mercaptopropionate), 1,6-hexanediol bis(3-mercaptopropionate), and 1,4-bis(mercaptopropylthiomethyl)benzene (corresponding to the bifunctional active hydrogen-containing compound (B32) constituting the urethane prepolymer (B12)).

Thiols such as trimethylolpropane tris(3-mercaptopropionate), pentaerythritol tetrakis(3-mercaptopropionate), dipentaerythritol hexakis(3-mercaptopropionate), 1,2-bis[(2-mercaptoethyl)thio]-3-mercaptopropane, 2,2-bis(mercaptomethyl)-1,4-butanedithiol, 2,5-bis(mercaptomethyl)-1,4-dithiane, 4-mercaptomethyl-1,8-dimercapto-3,6-dithiaoctane, 1,1,1,1-tetrakis(mercaptomethyl)methane, 1,1,3,3-tetrakis(mercaptomethylthio)propane, 1,1,2,2-tetrakis(mercaptomethylthio)ethane, 4,6-bis(mercaptomethylthio)-1,3-dithiane, and tris-{(3-mercaptopropionyloxy)ethyl}isocyanurate.

### [OH/SH Type Polymerizable Group-Containing Monomer; Component (B3)]

The OH/SH type polymerizable group-containing monomer is a polymerizable monomer having both a hydroxy group and a thiol group.

2-mercaptoethanol, 1-hydroxy-4-mercaptocyclohexane, 2-mercaptohydroquinone, 4-mercaptophenol, 1-hydroxyethylthio-3-mercaptoethylthiobenzene, 4-hydroxy-4′-mercaptodiphenylsulfone, 2-(2-mercaptoethylthio)ethanol, dihydroxyethylsulfide mono(3-mercaptopropionate), dimercaptoethane mono(salicylate) (corresponding to the bifunctional active hydrogen-containing compound (B32) constituting the urethane prepolymer (B12)).

Polyfunctional OH/SH type polymerizable group-containing monomers such as 3-mercapto-1,2-propanediol, glycerin di(mercaptoacetate), 2,4-dimercaptophenol, 1,3-dimercapto-2-propanol, 2,3-dimercapto-1-propanol, 1,2-dimercapto-1,3-butanediol, pentaerythritol tris(3-mercaptopropionate), pentaerythritol mono(3-mercaptopropionate), pentaerythritol bis(3-mercaptopropionate), pentaerythritol tris(thioglycolate), pentaerythritol pentakis(3-mercaptopropionate), hydroxymethyl-tris(mercaptoethylthiomethyl)methane, and hydroxyethylthiomethyl-tris(mercaptoethylthio)methane.

### <(B4) Amino Group-Containing Monomer; Component (B4)>

The amino group-containing monomer (B4) used in the present invention is not particularly limited as long as it is a monomer having two or more primary and/or secondary amino groups in one molecule. The amino group-containing monomer is roughly classified into an aliphatic amine, an alicyclic amine, and an aromatic amine.

Specific examples of the amino group-containing monomer (B4) include the following.

### [Aliphatic Amine; Component (B4)]

Bifunctional amines such as ethylenediamine, hexamethylenediamine, nonamethylenediamine, undecanemethylenediamine, dodecamethylenediamine, metaxylenediamine, 1,3-propanediamine, and putrescine (corresponding to the bifunctional active hydrogen-containing compound (B32) constituting the urethane prepolymer (B12)).

Polyfunctional amines such as polyamines such as diethylenetriamine.

### [Alicyclic Amine; Component (B4)]

Bifunctional amines such as isophoronediamine and cyclohexyldiamine (corresponding to the bifunctional active hydrogen-containing compound (B32) constituting the urethane prepolymer (B12)).

### [Aromatic Amine; Component (B4)]

Bifunctional amines such as 4,4′-methylenebis(o-chloroaniline) (MOCA), 2,6-dichloro-p-phenylenediamine, 4,4′-methylenebis(2,3-dichloroaniline), 4,4′-methylenebis(2-ethyl-6-methylaniline), 3,5-bis(methylthio)-2,4-toluenediamine, 3,5-bis(methylthio)-2,6-toluenediamine, 3,5-diethyltoluene-2,4-diamine, 3,5-diethyltoluene-2,6-diamine, trimethyleneglycol-di-p-aminobenzoate, polytetramethyleneglycol-di-p-aminobenzoate, 4,4′-diamino-3,3′,5,5′-tetraethyldiphenylmethane, 4,4′-diamino-3,3′-diisopropyl-5,5′-dimethyldiphenylmethane, 4,4′-diamino-3,3′,5,5′-tetraisopropyldiphenylmethane, 1,2-bis(2-aminophenylthio)ethane, 4,4′-diamino-3,3′-diethyl-5,5′-dimethyldiphenylmethane, N,N′-di-sec-butyl-4,4′-diaminodiphenylmethane, 3,3′-diethyl-4,4′-diaminodiphenylmethane, m-xylylenediamine, N,N′-di-sec-butyl-p-phenylenediamine, m-phenylenediamine, p-xylylenediamine, p-phenylenediamine, 3,3′-methylenebis(methyl-6-aminobenzoate), 2-methylpropyl 2,4-diamino-4-chlorobenzoate, isopropyl 2,4-diamino-4-chlorobenzoate, isopropyl 2,4-diamino-4-chlorophenylacetate, di-(2-aminophenyl)thioethyl terephthalate, diphenylmethanediamine, tolylenediamine, and piperadine (corresponding to the bifunctional active hydrogen-containing compound (B32) constituting the urethane prepolymer (B12)).

Polyfunctional amines such as 1,3,5-benzenetriamine and melamine.

In the present invention, when the polymerizable functional group in the polyrotaxane monomer (A) is polymerized by sequential addition reaction (polycondensation/polyaddition reaction) with an active hydrogen-containing group to produce the rein, the polymerizable composition containing the component (A), the component (B1), the component (B2), the component (B3), and the component (B4) preferably has the following blending proportion. When the polymerizable functional group of the component (A) is an active hydrogen-containing group, the component (B1) is essential.

Specifically, it is preferable that the component (A) is contained in a range of 3 to 50 parts by mass and the component (B) is contained in a range of 50 to 97 parts by mass with respect to 100 parts by mass of the total amount of the component (B1), the component (B2), the component (B3), and the component (B4) (hereinafter simply referred to as “amount of the component (B)” in some cases) and the component (A). When the polyrotaxane monomer (A) is contained at this proportion, the obtained resin can exhibit excellent mechanical properties. In order to achieve the above effects, it is more preferable that the amount of the component (A) is in a range of 5 to 45 parts by mass and the amount of the component (B) is in a range of 55 to 95 parts by mass.

Further, when the amount of the component (B) is 100% by mass, it is preferable that the amount of the component (B1) is 0 to 100% by mass, the component (B2) is 0 to 100% by mass, the component (B3) is 0 to 80% by mass, and the component (B4) is 0 to 30% by mass, because excellent mechanical properties are exhibited. In order to further exhibit this effect, it is more preferable that the amount of the component (B1) is 20 to 95% by mass, the component (B2) is 0 to 20% by mass, the component (B3) is 0 to 70% by mass, and the component (B4) is 0 to 25% by mass, and it is most preferable that the amount of the component (B1) is 40 to 95% by mass, the component (B2) is 0 to 5% by mass, the component (B3) is 0 to 35% by mass, and the component (B4) is 0 to 20% by mass.

It is preferable that the ratio of the number of moles of all polymerizable functional groups capable of reacting with iso(thio)cyanate groups contained in the polyrotaxane monomer (A), the component (B2), the component (B3), and the component (B4) to the number of moles of all iso(thio)cyanate groups contained in the component (B1) satisfies 1:0.8 to 1.2.

On the other hand, when the polymerizable functional group in the polyrotaxane monomer (A) is chain-polymerized by radical polymerization, as described above, the polymerizable composition containing the component (A) and the following radical polymerizable monomer (B5) preferably has the following blending proportion.

Specifically, it is preferable that the component (A) is contained in a range of 3 to 50 parts by mass and the component (B5) is contained in a range of 50 to 97 parts by mass with respect to 100 parts by mass of the total of the component (A) and the component (B5). When the polyrotaxane monomer (A) is contained at this proportion, the obtained resin can exhibit excellent mechanical properties. In order to achieve the above effects, it is more preferable that the amount of the component (A) is in a range of 5 to 45 parts by mass and the amount of the component (B5) is in a range of 55 to 95 parts by mass.

### <(B5) Radical Polymerizable Monomer>

In the present invention, the radical polymerizable monomer (B5) is not particularly limited as long as it has a radical polymerizable group. In this case, the polymerizable functional group contained in the rotaxane monomer (A) is a radical polymerizable group. The polymerizable composition contains at least the component (A) and the component (B5).

The radical polymerizable monomer (B5) can be roughly classified into a (meth)acrylate compound having a (meth)acrylate group, a vinyl compound having a vinyl group, and an allyl compound having an allyl group.

As preferable specific examples of the radical polymerizable monomer (B5), those described in WO2015/068798 can be used.

### <Preferred Polymerizable Composition>

The above polyrotaxane monomer (A) and polymerizable monomer (B) are not particularly limited, and the above compositions can be used, and among them, the polymerizable composition used for the under layer of the preferred laminated polishing pad is preferably one in which the polymerizable functional group of the cyclic molecules of the polyrotaxane monomer (A) is selected from a hydroxy group, a thiol group, and an amino group, and the polymerizable monomer (B) contains the iso(thio)cyanate compound (B1). By selecting from these, an excellent resin can be produced. In particular, among the iso(thio)cyanate compounds (B1), it is preferable to contain the urethane prepolymer (B12). In this way, excellent mechanical properties and the compression ratio of the under layer can be easily adjusted. Among them, it is particularly preferable that the polymerizable functional group of the rotaxane monomer (A) contains at least a hydroxy group and the iso(thio)cyanate compound (B1) contained in the polymerizable monomer (B) contains the urethane prepolymer (B12).

Among them, it is preferable that the polymerizable monomer (B) contains the iso(thio)cyanate compound (B1) and the (thi)ol compound (B3) and/or the amino group-containing monomer (B4). In this case, the iso(thio)cyanate compound (B1) is more preferably the urethane prepolymer (B12). It is particularly preferable that the (thi)ol compound (B3) and/or the amino group-containing monomer (B4) contain at least one or more of the (thi)ol compounds (B3).

### (Other Components Blended in the Polymerizable Composition)

In the polymerizable composition used in the present invention, depending on the type of the polymerizable functional group introduced into the polyrotaxane monomer (A) or the polymerizable monomer (B) described above, various (C) polymerization curing accelerators may be used in order to rapidly accelerate the polymerization.

For example, when the polymerizable functional group of the polyrotaxane monomer (A) is a hydroxy group, an amino group, an epoxy group, or a thiol group and the component (B) contains the iso(thio)cyanate compound (B1), (C1) a reaction catalyst for urethane or urea or (C2) a condensing agent is used as the polymerization curing accelerator.

When the polymerizable functional group of the polyrotaxane monomer (A) is a polymerizable functional group such as a hydroxy group and an amino group and the component (B) contains the epoxy group-containing monomer (B2), (C3) an epoxy curing agent or (C4) a cationic polymerization catalyst for ring-opening polymerization of epoxy groups is used as the polymerization curing accelerator.

Further, when the polymerizable functional group of the polyrotaxane monomer (A) is a radical polymerizable group and the component (B) contains the radical polymerizable monomer (B5), (C5) a radical polymerization initiator is used as the polymerization curing accelerator.

Specific examples of the polymerization accelerators (C1) to (C5) that can be suitably used in the present invention include those described in WO2015/068798.

These various polymerization curing accelerators (C) may be used alone or in combination of two or more, but the amount used may be a so-called catalytic amount, for example, a small amount in a range of 0.001 to 10 parts by mass, particularly 0.01 to 5 parts by mass, based on 100 parts by mass of the total of the polyrotaxane monomer (A) and the polymerizable monomer (B).

The polymerizable composition used in the present invention may further contain various known blending agents as long as the effects of the present invention are not impaired. For example, abrasive grains, antioxidants, ultraviolet absorbers, infrared absorbers, coloring inhibitors, fluorescent dyes, dyes, photochromic compounds, pigments, fragrances, surfactants, flame retardants, plasticizers, fillers, antistatic agents, foam stabilizers, solvents, leveling agents, and other additives may be added. These additives may be used alone or in combination of two or more kinds thereof. These additives can be incorporated into the resin by incorporating the additives into a polymerizable composition and polymerizing the polymerizable composition.

As the polymerization method, a known method can be employed. In the case of polycondensation or polyaddition reaction, conditions described in WO2015/068798, WO2016/143910, and JP 2017-48305 A can be employed. In the case of radical polymerization, conditions described in WO2014/136804 and WO2015/068798 can be employed.

In the present invention, the resin obtained by polymerizing the polymerizable composition may be a foamed resin obtained by foaming the resin. A foamed resin or a non-foamed resin may be selected depending on the desired compression ratio and hardness, but the under layer of the present invention is more preferably a foamed resin from the viewpoint of controlling the compression ratio and hardness, and among them, a foamed polyurethane (urea) resin is more preferable. As a method for foaming the resin, any known foaming method can be used without any limitation. Examples of these methods include a foaming agent foaming method in which a volatile foaming agent such as a low boiling point hydrocarbon or water is added, a method in which hollow particles are dispersed and cured, a method in which heat-expandable fine particles are mixed and heated to foam the fine particles, and a mechanical froth foaming method in which air or an inert gas such as nitrogen is blown during mixing.

The resin when foamed preferably has a density of 0.4 to 0.9 g/cm³. When a polymerizable composition containing an iso(thio)cyanate group as a polymerizable functional group is used, in the foaming agent foaming method in which water is added, water reacts with the iso(thio)cyanate group to form carbon dioxide and an amino group, and carbon dioxide serves as a foaming gas, while the amino group further reacts with the iso(thio)cyanate group to form a urea bond and/or a thiourea bond.

The CMP laminated polishing pad of the present invention includes at least a polishing layer and an under layer, wherein the under layer contains a resin obtained by polymerizing the polymerizable composition.

In the present invention, the under layer may be not only a layer made of a foamed resin or a non-foamed resin but also a layer obtained by impregnating a nonwoven fabric with the polymerizable composition and polymerizing the composition. For example, it is preferable to impregnate the nonwoven fabric with a polymerizable composition capable of forming a polyurethane (urea) resin by polymerization and polymerize the composition. Thus, a nonwoven fabric containing a polyurethane (urea) resin is obtained, which can be used as an under layer.

Examples of such a nonwoven fabric include a polyester nonwoven fabric, a nylon nonwoven fabric, and an acrylic nonwoven fabric. In particular, it is preferably a layer obtained by impregnating the nonwoven fabric with a polymerizable composition containing the component (A) and the component (B1) and polymerizing the composition.

The content of the resin obtained by polymerizing the polymerizable composition containing the component (A) and the component (B) in the under layer of the present invention is preferably 30% by mass or more, more preferably 50% by mass or more, and still more preferably 80% by mass or more based on the total amount of the under layer.

In the present invention, the under layer is not particularly limited, but it is preferable that the compression ratio is within a certain range in order to improve uniformity of polishing. The compression ratio can be measured, for example, by a method in accordance with JIS L 1096. The compression ratio of the under layer is preferably 1.0% to 40%, and more preferably 1.5% to 30%. When it is within the above range, excellent flatness of the object to be polished can be exhibited.

Also, the under layer may have any suitable hardness. The hardness can be measured according to the Shore method, for example, according to the JIS standard (hardness test) K6253. The under layer preferably has a Shore hardness of less than 50D. With this hardness, the cushioning effect as the under layer is easily exhibited. The hardness is more preferably 20A to 40D (“A” indicates the hardness on the Shore “A” scale, and “D” indicates the hardness on the Shore “D” scale). Any hardness may be obtained by changing the blending composition and the blending amount as necessary.

In addition, since the under layer has a low hysteresis loss property or an excellent elastic recovery property, when it is used as a CMP laminated polishing pad, flatness of an object to be polished and a high polishing rate can be exhibited. The hysteresis loss can be measured, for example, by a method in accordance with JIS K 6251. Specifically, a test piece prepared in a dumbbell shape is elongated by 100% and then returned to its original state, whereby hysteresis loss [(area of elongation and stress when elongated and returned to its original state)/(area of elongation and stress when elongated)×100] can be measured.

The hysteresis loss of the under layer is not particularly limited, but is preferably 40% or less, more preferably 30% or less, and still more preferably 20% or less. When the hysteresis loss is in this range, not only the polishing uniformity is improved but also the polishing rate is improved.

Although the thickness of the under layer is not particularly limited, it is preferably 0.1 to 2 mm, and more preferably 0.2 to 1.8 mm.

The CMP laminated polishing pad of the present invention includes the under layer and the polishing layer described above. The polishing layer is provided on one side of the under layer. As will be described later, an intermediate layer may be provided between the under layer and the polishing layer.

The material constituting the polishing layer of the CMP laminated polishing pad of the present invention is not particularly limited, and examples thereof include a urethane (urea) resin, a nonwoven fabric, and the like. In the present invention, a polishing layer made of a urethane (urea) resin is particularly preferred, and the polishing layer is more preferably a foam. More preferably, the polishing layer is made of a thermosetting urethane (urea) resin.

The urethane (urea) resin used for the CMP laminated polishing pad is not particularly limited and may be prepared by a known method, for example, by polymerizing a urethane (urea) resin composed of a compound having an isocyanate group and a compound having an active hydrogen group having an active hydrogen polymerizable with an isocyanate group, such as a hydroxy group, a thiol group, and an amino group. In addition, the polyrotaxane monomer (A) having at least two polymerizable functional groups in the molecule used in the present invention can also be used.

A method for polymerizing the urethane (urea) resin is not particularly limited, and a known method may be employed, and conditions described in WO2015/068798, WO2016/143910, and JP 2017-48305 A may be employed as in the under layer. Specifically, a dry method such as a one pot method or a prepolymer method, a wet method using a solvent, or the like can be used. Among them, the dry method is preferably employed.

In addition, the foaming method in the case of foaming the polishing layer is not particularly limited, and for example, a foaming method similar to the method described in the under layer may be selected. Among them, the most preferable foaming method for the polishing layer is, for example, a foaming method using hollow particles as shown below.

The hollow particles (microballoons) used in the present invention (hereinafter also referred to as component (D)) may also be blended. As the component (D), known components can be used without any limitation. Specific examples thereof include hollow particles in which vinylidene chloride resin, (meth)acrylate resins, acrylonitrile-vinylidene chloride copolymers, epoxy resins, phenol resins, melamine resins, urethane (urea) resins, and the like form an outer shell. Among them, hollow particles composed of an outer shell portion made of a urethane-based resin and a hollow portion surrounded by the outer shell portion are preferable.

The compression ratio of the polishing layer of the CMP laminated polishing pad of the present invention is preferably 0.1% to 20%, and more preferably 0.5% to 10%. Further, in the CMP laminated polishing pad of the present invention, it is more preferable that the compression ratio of the under layer is larger than the compression ratio of the polishing layer. Within this range, the CMP laminated polishing pad of the present invention can exhibit excellent polishing characteristics.

The Shore hardness of the polishing layer of the CMP laminated polishing pad of the present invention is preferably in a range of 50A to 90D, and more preferably the Shore hardness of the under layer is smaller than the Shore hardness of the polishing layer. Within this range, the CMP laminated polishing pad of the present invention can exhibit excellent polishing characteristics.

Although the thickness of the polishing layer is not particularly limited, it is preferably 0.1 to 2 mm, and more preferably 0.2 to 1.8 mm.

In the CMP laminated polishing pad of the present invention, the polishing layer and the under layer may be bonded to each other by a known method. For example, an intermediate layer for bonding (fixing) the polishing layer and the under layer may be provided between the polishing layer and the under layer, or the polishing layer and the under layer may be directly bonded to each other. Direct bonding of the polishing layer and the under layer means to take a structure having a crosslinked structure between the polishing layer and the under layer, or to take a structure having an electrostatic bond, or to take an anchor effect of mechanical interaction. The electrostatic bonding may include van der Waals or hydrogen-bonding interactions between the under layer and the polishing layer. These can be obtained, for example, by polymerizing the under layer or polishing layer and then subsequently polymerizing the polishing layer or under layer on that layer.

The intermediate layer for bonding (fixing) the polishing layer and the under layer may be any known intermediate layer without limitation. Such an intermediate layer preferably has a thickness of 30 to 300 μm, and more preferably 30 to 150 μm. The intermediate layer can be selected as an adhesive from a pressure sensitive adhesive, a hot melt adhesive, or a combination thereof. Specifically, a pressure sensitive type or a hot melt type such as an acrylic type, a butadiene type, an isoprene type, an olefin type, a styrene type or an isocyanate type is preferably used. The intermediate layer may include a polyethylene terephthalate film, an oriented polypropylene film, a nonwoven fabric, or the like as a base material. Usually, the base material having a thickness of 20 to 200 μm is used.

Further, a back surface tape layer for fixing to a polishing surface plate may be provided on the back surface side of the under layer. The back surface tape layer is usually provided with an adhesive layer on a plastic film or a release paper, and when the pad is attached to a surface plate during polishing, the plastic film or the release paper (referred to as a separator) is peeled off and the pad is pressed against the surface plate to fix the pad to the surface plate. The back surface tape layer may be the same as the intermediate layer.

Although the polishing layer of the CMP laminated polishing pad of the present invention is not particularly limited, a groove structure may be formed on the surface thereof. In particular, when a polishing layer made of a urethane (urea) resin is used, it is preferable that the groove structure has a shape capable of holding and renewing the slurry when polishing the member to be polished. Specific examples thereof include X (stripe) grooves, XY lattice grooves, concentric grooves, through holes, non-through holes, polygonal columns, cylinders, spiral grooves, eccentric circular grooves, radial grooves, and combinations of these grooves.

The method of forming the groove structure is not particularly limited. Examples thereof include a method of mechanical cutting using a jig such as a bite of a predetermined size, a method of pouring a resin into a mold having a predetermined surface shape and curing the resin, a method of pressing a resin with a press plate having a predetermined surface shape, a method of using photolithography, a method of using a printing technique, and a method of using a laser beam such as a carbon dioxide laser.

### EXAMPLES

Next, the present invention will be described in detail with reference to Examples and Comparative Examples, but the present invention is not limited to these Examples. In the following Examples and Comparative Examples, the above-mentioned components and evaluation methods are as follows.

### [Measurement Method]

### (Molecular Weight Measurement; Gel Permeation Chromatography (GPC Measurement))

In the GPC measurement, a liquid chromatograph (manufactured by Nihon Waters K.K.) was used as an apparatus. As the column, Shodex GPC KF-802 (exclusion limit molecular weight: 5,000), KF802.5 (exclusion limit molecular weight: 20,000), KF-803 (exclusion limit molecular weight: 70,000), KF-804 (exclusion limit molecular weight: 400,000) or KF-805 (exclusion limit molecular weight: 2,000,000) manufactured by Showa Denko K.K. was appropriately used depending on the molecular weights of the samples to be analyzed. In addition, dimethylformamide was used as a developing solution, and measurement was performed under the conditions of a flow rate of 1 mL/min and a temperature of 40° C. Using polystyrene as a standard sample, the weight average molecular weight was determined by comparative conversion. A differential refractometer was used as a detector.

### [Components]

### <(A) Polyrotaxane Monomer>

RX-1: a polyrotaxane monomer having a hydroxy group in a side chain thereof, having an average molecular weight of the side chain of about 350 and a weight average molecular weight of 165,000, produced by the following method.

### (Production Method of RX-1)

Linear polyethylene glycol (PEG) having a molecular weight of 10,000 was prepared as a polymer for axis molecule, and PEG: 10 g, TEMPO (2,2,6,6-tetramethyl-1-piperidinyloxy radical): 100 mg, and sodium bromide: 1 g were dissolved in 100 mL of water. An aqueous sodium hypochlorite solution (effective chlorine concentration: 5%): 5 mL was added to this solution, and the mixture was stirred at room temperature for 10 minutes. Thereafter, ethanol: 5 mL was added to terminate the reaction. Then, after extraction was performed using methylene chloride: 50 mL, methylene chloride was distilled off, the residue was dissolved in ethanol: 250 mL, reprecipitated at a temperature of −4° C. for 12 hours, and PEG-COOH was recovered and dried.

PEG-COOH: 3 g prepared above and α-cyclodextrin (α-CD): 12 g were each dissolved in 50 mL of water at 70° C., and the resulting solutions were mixed and shaken well. Then, the mixed solution was reprecipitated at a temperature of 4° C. for 12 hours, and the precipitated clathrate complex was recovered by freeze-drying. Thereafter, 0.13 g of adamantanamine was dissolved in dimethylformamide (DMF): 50 mL at room temperature, and then the above clathrate complex was added thereto and rapidly shaken well. Subsequently, a solution in which 0.38 g of benzotriazole-1-yl-oxy-tris(dimethylamino)phosphonium hexafluorophosphate reagent was dissolved in 5 mL of DMF was further added and shaken well. Further, a solution obtained by dissolving 0.14 mL of diisopropylethylamine in 5 mL of DMF was added and shaken well to obtain a slurry reagent.

The slurry reagent obtained above was allowed to stand at 4° C. for 12 hours. Thereafter, a mixed solution of DMF/methanol (volume ratio 1/1): 50 mL was added, mixed and centrifuged, and the supernatant was discarded. Further, after washing with the DMF/methanol mixed solution, washing with methanol and centrifugation were performed to obtain a precipitate. The obtained precipitates were dried by vacuum drying, then dissolved in dimethyl sulfoxide (DMSO): 50 mL, and the obtained transparent solution was dropped into 700 mL of water to precipitate polyrotaxane. The precipitated polyrotaxane was recovered by centrifugation and vacuum-dried. Further, it was dissolved in DMSO, precipitated in water, recovered, and dried to obtain a purified polyrotaxane. The clathrate number of α-CD at this time was 0.25.

Here, the clathrate number was determined by dissolving the polyrotaxane in DMSO-d6, measuring with a ¹H-NMR measuring device (JNM-LA500 manufactured by JEOL Ltd.), and calculating by the following method.

Here, X, Y and X/(Y−X) have the following meanings.

X: Integral value of proton derived from hydroxy group of cyclodextrin at 4 to 6 ppm

Y: Integral value of proton derived from methylene chain of cyclodextrin and PEG at 3 to 4 ppm

X/(Y−X): Proton ratio of cyclodextrin to PEG

First, X/(Y−X) at a theoretically maximum clathrate number of 1 was calculated in advance, and the clathrate number was calculated by comparing this value with X/(Y−X) calculated from an analysis value of an actual compound.

500 mg of the polyrotaxane purified above was dissolved in 50 mL of 1 mol/L NaOH aqueous solution, 3.83 g (66 mmol) of propylene oxide was added thereto, and the solution was stirred at room temperature under an argon atmosphere for 12 hours. Next, the polyrotaxane solution was neutralized so as to have a pH of 7 to 8 using a 1 mol/L HCl aqueous solution, dialyzed using a dialysis tube, and freeze-dried to obtain a hydroxypropylated polyrotaxane. The obtained hydroxypropylated polyrotaxane was identified by ¹H-NMR and GPC, and confirmed to be a hydroxypropylated polyrotaxane having a desired structure.

In addition, the degree of modification of a cyclic molecule to a hydroxy group by a hydroxypropyl group was 0.5, and the weight average molecular weight Mw was 50,000 by GPC measurement.

The obtained hydroxypropylated polyrotaxane: 5 g was dissolved in ε-caprolactone: 15 g at 80° C. to prepare a mixed solution. After the mixed solution was stirred at 110° C. for 1 hour while blowing dry nitrogen, then 0.16 g of a 50 wt % xylene solution of tin(II) 2-ethylhexanoate was added and stirred at 130° C. for 6 hours. Thereafter, xylene was added to obtain an ε-caprolactone-modified polyrotaxane xylene solution in which a side chain having a nonvolatile concentration of about 35% by mass was introduced.

The ε-caprolactone-modified polyrotaxane xylene solution prepared above was dropped into hexane, recovered, and dried to obtain an ε-caprolactone-modified polyrotaxane (RX-1).

The physical properties of the polyrotaxane monomer (A); RX-1 were as follows.

Polyrotaxane weight average molecular weight Mw (GPC): 165,000

Degree of modification of the side chain: 0.5 (50% expressed as %)

Molecular weight of the side chain: about 350 on average

<(B) Polymerizable Monomer Other than Polyrotaxane Monomer (A) having at Least Two Polymerizable Functional Groups in a Molecule>

Component (B1): a polyfunctional isocyanate compound having at least two isocyanate groups

Component (B12): a urethane prepolymer

Pre-1: an isocyanate-terminated urethane prepolymer having an iso(thio)cyanate equivalent of 905 prepared by the following method

### (Production Method of Pre-1)

In a flask equipped with a nitrogen inlet tube, a thermometer, and a stirrer, 2,4-tolylene diisocyanate: 50 g, polyoxytetramethylene glycol (number average molecular weight: 1,000): 90 g, and diethylene glycol: 12 g were reacted at 80° C. for 6 hours in a nitrogen atmosphere to obtain an isocyanate-terminated urethane prepolymer (Pre-1) having an isocyanate equivalent of 905.

Pre-2: Isocyanate-terminated urethane prepolymer having an iso(thio)cyanate equivalent of 750 prepared by the following method

### (Production Method of Pre-2)

In a flask equipped with a nitrogen inlet tube, a thermometer, and a stirrer, 2,4-tolylene diisocyanate: 69 g and polyoxytetramethylene glycol (number average molecular weight: 1,000): 210 g were reacted for 6 hours in a nitrogen atmosphere to obtain an isocyanate-terminated urethane prepolymer (Pre-2) having an isocyanate equivalent of 750.

Component (B3):

TMP; trimethylolpropane

PEG600; polyethylene glycol having a number average molecular weight of 600

Component (B4):

MOCA; 4,4′-methylenebis(o-chloroaniline)

### <(D) Hollow Particles>

Hollow Particles 1: Microcapsule 920-40 (manufactured by Japan Fillite Co., Ltd.) having a hollow particle diameter of 40 μm and a density of 0.03 g/cm³.

### <Other Component>

L5617: Silicone foam stabilizer manufactured by Momentive

### [Evaluation Items]

(1) Density: The density was measured with (DSG-1) manufactured by Toyo Seiki Seisaku-sho, Ltd.

(2) Compression ratio: The compression ratio was measured according to a method in accordance with JIS L 1096.

That is, the thickness at a pressure of 0.1 kPa was taken as an initial thickness t0 mm, and then the thickness t1 mm after being applied at 34.5 kPa for 60 seconds was measured. Thereafter, the compression ratio was calculated from the following equation.

Compression ratio (%)=100×(t0−t1)/t0

(3) Shore hardness: The Shore hardness was measured with a durometer manufactured by Kobunshi Keiki Co., Ltd. in accordance with JIS standard (hardness test) K6253.

(4) Hysteresis loss: A resin punched out in the shape of dumbbell No. 8 having a thickness of 2 mm was stretched by 20 mm at a rate of 10 mm/min with an autograph of AG-SX manufactured by Shimadzu Corporation, and the hysteresis loss was measured when the stress was returned to 0.

(5) Polishing rate: The polishing conditions are shown below.

Object to be polished: 4-inch sapphire wafer

Slurry: FUJIMI COMPOL-80 stock solution manufactured by Fujimi Incorporated

Pressure: 4 Psi

Rotational speed: 45 rpm

Time: 1 hour

The polishing rate (μm/hr) when the polishing was performed under the above conditions was measured. The polishing rate is an average value of 100 wafers.

(6) Scratch resistance: The presence or absence of scratches on 100 wafers polished under the conditions described in (5) above was observed. The evaluation was performed based on the following criteria

1: All 100 wafers are free of defects as measured with a laser microscope.

2: Defects are visible on 1 or 2 wafers out of 100 wafers measured with a laser microscope.

3: Defects are visible on 3 to 5 wafers out of 100 wafers measured with a laser microscope.

4: Defects are visible on 6 to 9 wafers out of 100 wafers measured with a laser microscope.

5: Defects are visible on 10 or more wafers out of 100 wafers measured with a laser microscope.

### Example 1

### (Production Method of Under Layer)

RX-1 (24.9 parts by mass) of Component (A) and TMP (1.7 parts by mass) of Component (B3) were mixed at 120° C. to make a uniform solution, followed by sufficient deaeration to prepare Liquid A.

Separately, L5617 (1.5 parts by mass) of the other component was added to Pre-1 (73.4 parts by mass) of Component (B) which was heated to 70° C., and the mixture was vigorously stirred at 2000 rpm in a nitrogen atmosphere using a stirrer equipped with a stirring blade as a beater, and air bubbles were taken in by a mechanical froth method to prepare Liquid B. Then, the above-prepared Liquid A was poured into the mixture, and again, the mixture was vigorously stirred at 2000 rpm in a nitrogen atmosphere using a stirrer equipped with a stirring blade as a beater, and air bubbles were taken in by a mechanical froth method to obtain a uniform polymerizable composition having a foam structure, and the polymerizable composition was poured into a mold and polymerized at 100° C. for 15 hours. After completion of the polymerization, the polymerized resin was removed to obtain a foamed resin. The obtained foamed resin was sliced to obtain an under layer having a thickness of 1.5 mm. Each blending amount is shown in Table 1. The obtained under layer had a density of 0.7 g/cm³, compression ratio of 7%, Shore hardness of 14D, and hysteresis loss of 3%.

### (Production Method of Polishing Layer-1)

Hollow particles 1 (0.8 parts by mass) of Component (D) were added to Pre-1 (87.7 parts by mass) of Component (B) produced above and heated to 70° C., and the mixture was stirred with a rotating and revolving stirrer to prepare a uniform solution, and 4,4′-methylenebis(o-chloroaniline) (MOCA) (12.3 parts by mass) heated at 120° C. was added thereto and uniformly mixed to obtain a polymerizable composition. The polymerizable composition was poured into a mold and cured at 100° C. for 15 hours. After completion of curing, the urethane (urea) resin was removed from the mold to obtain a cured body.

The obtained cured body was sliced to obtain a urethane resin having a thickness of 1 mm. A spiral groove was formed on the surface of the urethane resin to obtain a polishing layer made of a urethane resin having a size of 500 mmφ and a thickness of 1 mm. Each blending amount is shown in Table 1. The obtained polishing layer had a density of 0.8 g/cm³, compression ratio of 0.7%, Shore hardness of 55D, and hysteresis loss of 60%.

### (Production Method of CMP Laminated Polishing Pad)

The under layer and the polishing layer obtained above were bonded together using Hybon YR713-1W (80 μm thick, manufactured by Hitachi Chemical Polymer Co., Ltd.) as a hot melt adhesive to obtain a CMP laminated polishing pad. Further, a double-sided tape was attached to the back surface of the CMP laminated polishing pad with a pressure sensitive adhesive. The obtained CMP laminated polishing pad had a polishing rate of 2.2 μm/hr and scratch resistance of 1.

### Examples 2 and 3, Comparative Examples 1 and 2

CMP laminated polishing pads were produced and evaluated in the same manner as in Example 1 except that polymerization was performed with the composition shown in Table 1. Comparative Example 2 is a single-layer polishing pad having only a polishing layer. The blending proportion of each component and the results are summarized in Table 1.

TABLE 1

| | | Polymerizable composition (part by mass) | | | | Evaluation results | | | | | |
|---|---|---|---|---|---|---|---|---|---|---|---|
| | | | | | | | Com- | | | Polishing | |
| | | Component | Component | Component | | Shore | pression | Density | Hysteresis | rate | Scratch |
| | | (A) | (B) | (D) | Others | hardness | ratio (%) | (g/cm³) | loss (%) | (μm/hr) | resistance |
| Example 1 | Under | RX-1 (24.9) | Pre-1 (73.4) | — | L5617 | 14D | 7.0 | 0.7 | 3 | 2.2 | 1 |
| | layer | | TMP (1.7) | | (1.5) | | | | | | |
| | Polishing | — | Pre-1 (87.7) | Hollow | — | 55D | 0.7 | 0.8 | 60 | | |
| | layer | | MOCA (12.3) | particles 1 | | | | | | | |
| | | | | (0.8) | | | | | | | |
| Example 2 | Under | RX-1 (13.7) | Pre-2 (67.1) | — | L5617 | 47A | 10.0 | 0.7 | 3 | 2.3 | 1 |
| | layer | | PEG600 (19.2) | | (1.5) | | | | | | |
| | Polishing | — | Pre-1 (87.7) | Hollow | — | 55D | 0.7 | 0.8 | 60 | | |
| | layer | | MOCA (12.3) | particles 1 | | | | | | | |
| | | | | (0.8) | | | | | | | |
| Example 3 | Under | RX-1 (2.9) | Pre-1 (85.7) | — | L5617 | 50D | 1.0 | 0.7 | 50 | 1.5 | 2 |
| | layer | | MOCA (11.4) | | (1.5) | | | | | | |
| | Polishing | — | Pre-1 (87.7) | Hollow | — | 55D | 0.7 | 0.8 | 60 | | |
| | layer | | MOCA (12.3) | particles 1 | | | | | | | |
| | | | | (0.8) | | | | | | | |
| Comparative | Under | — | Pre-1 (95.5) | — | L5617 | 20D | 2.0 | 0.7 | 40 | 1.2 | 3 |
| Example 1 | layer | | TMP (4.5) | | (1.5) | | | | | | |
| | Polishing | — | Pre-1 (87.7) | Hollow | — | 55D | 0.7 | 0.8 | 60 | | |
| | layer | | MOCA (12.3) | particles 1 | | | | | | | |
| | | | | (0.8) | | | | | | | |
| Comparative | Under | — | | | | | | | | 1.0 | 5 |
| Example 2 | layer | | | | | | | | | | |
| | Polishing | — | Pre-1 (87.7) | Hollow | — | 55D | 0.7 | 0.8 | 60 | | |
| | layer | | MOCA (12.3) | particles 1 | | | | | | | |
| | | | | (0.8) | | | | | | | |

As is clear from the above Examples and Comparative Examples, it is clear that excellent polishing characteristics are exhibited by applying the under layer produced using the polyrotaxane of Component (A) to the CMP laminated polishing pad.

1. A CMP laminated polishing pad comprising at least a polishing layer and an under layer, wherein the under layer comprises a resin obtained by polymerizing a polymerizable composition containing: (A) a polyrotaxane monomer having at least two polymerizable functional groups in a molecule; and (B) a polymerizable monomer other than the polyrotaxane monomer (A) having at least two polymerizable functional groups in a molecule.

2. The CMP laminated polishing pad according to claim 1, wherein the content of the polyrotaxane monomer (A) having at least two polymerizable functional groups in a molecule in the polymerizable composition is 3 to 50 parts by mass with respect to 100 parts by mass of the sum of the content of the polyrotaxane monomer (A) having at least two polymerizable functional groups in a molecule and the content of the polymerizable monomer (B) other than the polyrotaxane monomer (A) having at least two polymerizable functional groups in a molecule.

3. The CMP laminated polishing pad according to claim 1, wherein the polyrotaxane monomer (A) having at least two polymerizable functional groups in a molecule is a polyrotaxane monomer in which a side chain having a polymerizable functional group is introduced into at least a part of a cyclic molecule in a composite molecular structure composed of an axis molecule and the cyclic molecule clathrating the axis molecule.

4. The CMP laminated polishing pad according to claim 1, wherein the polymerizable monomer (B) other than the polyrotaxane monomer (A) having at least two polymerizable functional groups in a molecule is an iso(thio)cyanate compound having at least two iso(thio)cyanate groups as polymerizable functional groups.

5. The CMP laminated polishing pad according to claim 1, wherein the under layer has a compression ratio of 1.0% or more and 40.0% or less.

6. The CMP laminated polishing pad according to claim 1, wherein the under layer has a Shore hardness of less than 50D.

7. The CMP laminated polishing pad according to claim 1, wherein a compression ratio of the under layer is larger than a compression ratio of the polishing layer, and a Shore hardness of the under layer is smaller than a Shore hardness of the polishing layer.

8. The CMP laminated polishing pad according to claim 1, wherein the under layer comprises a foamed polyurethane (urea) resin obtained by polymerizing the polymerizable composition.

9. The CMP laminated polishing pad according to claim 1, wherein the under layer is composed of a nonwoven fabric containing a polyurethane (urea) resin obtained by polymerizing the polymerizable composition.
